(19) United States
(12) Patent Application Publication
(10) Pub. No.: US 2025/0155802 A1
(43) Pub. Date: May 15, 2025

(54) Radiation-Sensitive Composition and Method for Forming Resist Pattern

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 18/839,677

(22) PCT Filed: Dec. 19, 2022
(86) PCT No.: PCT/JP2022/046747

§ 371 Date: Aug. 19, 2024

(30) Foreign Application Priority Data
Feb. 21, 2022 (JP) 2022-024933

(51) Int. Cl. G03F 7/004; C08K 5/372; C08K 5/42; G03F 7/00; G03F 7/039

(52) U.S. Cl. CPC G03F 7/0045; C08K 5/372; C08K 5/42; G03F 7/0392; G03F 7/70033

(57) ABSTRACT

A radiation-sensitive composition contains: (A) a polymer, and (B) a radiation-sensitive acid-generator formed of an onium cation and an organic anion having 4 or more iodine atoms, the onium cation having at least one group Rf¹ selected from the group consisting of a fluoroalkyl group and a fluoro group (excluding a fluoro group in the fluoroalkyl group).

### CROSS-REFERENCE TO RELATED APPLICATIONS

The present application claims the benefit of Japanese Patent Application No. 2022-024933 filed Feb. 21, 2022, the disclosure of which is incorporated herein by reference.

### TECHNICAL FIELD

The present disclosure relates to a radiation-sensitive composition and to a method for forming a resist pattern (hereinafter may also be referred to as a “resist pattern formation method”).

### BACKGROUND ART

In a lithography technique employed in production of various electronic devices including semiconductor devices and liquid crystal devices, a process target formed of a radiation-sensitive composition is irradiated with a far-UV ray (e.g., ArF excimer laser light), an extreme UV (EUV) ray, an electron beam, or the like, to thereby generate acid in a radiation-exposed part. Through chemical reaction involving the generated acid, difference in dissolution rate with respect to a developer is provided between the radiation-exposed part and a radiation-unexposed part. Thus, a resist pattern is formed on a substrate.

Meanwhile, structures of such electronic devices have been further miniaturized steeply. Under such circumstances, further fine resist patterns are required in lithography steps. In addition, in order to satisfy the requirement of further fine resist patterns, various studies have been done for improving resolution of a chemically amplified radiation-sensitive composition employed in lithographic micro-processing, rectangularity of a resultant resist pattern, and the like (see, for example, Patent Document 1). Patent Document 1 proposes a chemically amplified resist composition which contains an acid-generating agent including a triarylsulfonium cation having one or more fluorine atom, and a resin including a repeating unit having a phenolic hydroxy group.

### PRIOR ART DOCUMENTS

### Patent Documents

Patent Document 1: Japanese Patent Application Laid-Open (kokai) No. 2014-2359

### SUMMARY OF THE INVENTION

### Problems to be Solved by the Invention

Meanwhile, in a rapid progress in further process shrinkage of resist patterns in recent years, attempts have been made to form a pattern having, for example, a line width of 40 nm or less. Thus, the radiation-sensitive composition for forming a resist film must provide a suitable resist pattern by a small dose, when the composition is also employed in formation of such fine resist patterns. Even though the radiation-sensitive composition exhibits high sensitivity, in the case where diffusion of the acid generated in the resist film though exposure to a radiation cannot satisfactorily be controlled, uniformity in dimension of the resist pattern may decrease. Thus, the radiation-sensitive composition for forming a resist film must also exhibit excellent critical dimension uniformity (CDU) performance.

The present disclosure has been made in view of the aforementioned problems. Thus, an object of the present disclosure is to provide a radiation-sensitive composition which can provide both high sensitivity and CDU performance. Another object is to provide a method for forming such a resist pattern.

### Means for Solving the Problems

According to the present disclosure, the following means are provided.

[1] A radiation-sensitive composition includes (A) a polymer, and (B) a radiation-sensitive acid-generator formed of an onium cation and an organic anion having 4 or more iodine atoms, the onium cation having at least one group Rf¹ selected from the group consisting of a fluoroalkyl group and a fluoro group (excluding a fluoro group in the fluoroalkyl group).

[2] A resist pattern formation method includes a step of forming a resist film on a substrate by applying the radiation-sensitive composition of [1] above, a step of exposing the resist film to a radiation, and a step of developing the exposed resist film.

### Advantageous Effects of the Invention

According to the radiation-sensitive composition and the resist pattern formation method of the present disclosure, a resist pattern exhibiting excellent CDU performance can be formed at a small dose.

### MODES FOR CARRYING OUT THE INVENTION

### <<Radiation-Sensitive Composition>>

The radiation-sensitive composition of the present disclosure (hereinafter may also be referred to as “the present composition”) is a polymer composition containing a polymer (A) and a radiation-sensitive acid-generator. The present composition contains, as a radiation-sensitive acid-generator, an onium salt formed of a radiation-sensitive onium cation and an organic anion, which is a conjugate base of the corresponding acid. The organic anion is generally an anion formed by removing a proton from the acid residue of the organic acid. The radiation-sensitive acid-generator releases an organic anion via decomposition of the radiation-sensitive onium cation by the action of radiation, and the thus-released organic anion bonds to hydrogen extracted from a component contained in the present composition (e.g., the radiation-sensitive acid-generator itself or a solvent), whereby an acid originating from the organic anion is generated. Each of the radiation-sensitive acid-generator and the onium salt serving as an radiation-sensitive acid-generator contained in the present composition may be a single species or a combination of two or more species.

The present composition contains, as a radiation-sensitive acid-generator, a radiation-sensitive acid-generator which is formed of an onium cation and an organic anion having 4 or more iodine atoms, the onium cation having at least one group Rf¹ selected from the group consisting of a fluoroalkyl group and a fluoro group (excluding a fluoro group in the fluoroalkyl group) (hereinafter may also be referred to as a “acid-generator (B)”). In the present specification, the onium cation having group Rf¹ may be referred to as a “particular cation”, and the organic anion having 4 or more iodine atoms may be referred to as a “particular anion”.

The acid-generator (B) contained in the present composition may be a radiation-sensitive acid-generating agent or an acid diffusion control agent, or may contain both. The acid-generating agent is defined as a component which generates a strong acid in the present composition, wherein the agent can release an acid-releasable group included in a component of the radiation-sensitive composition from the component through exposure to a radiation. The acid diffusion control agent is a component which suppresses diffusion of the acid generated through light exposure and originating from the acid-generating agent in the resist film, to thereby suppress chemical reaction caused by the acid in the radiation-unexposed part. When the present composition contains two or more onium salt compounds as radiation-sensitive acid-generators, the onium salt compounds are classified into an acid-generating agent and an acid diffusion control agent, depending on the relative acid strength. The acid-generator (B) is preferably a compound that can generate a sulfonic acid, a carboxylic acid, or a sulfonamide in the composition upon exposure to the radiation.

In the present specification, the radiation-sensitive acid-generating agent formed of an onium cation having group Rf¹ and an organic anion having 4 or more iodine atoms may also be referred to as an “acid-generating agent (B-1)”, and the acid diffusion control agent formed of an onium cation having group Rf¹ and an organic anion having 4 or more iodine atoms may also be referred to as an “acid diffusion control agent (B-2)”. The acid-generator (B) is a compound different from the polymer (i. e., a low-molecule compound) and having no repeating unit derived from a monomer.

Specific embodiments of the present composition include the following embodiments <1> and <2>;
<1> An embodiment of the composition containing the polymer (A), the acid-generating agent (B-1), and a solvent (D); and
<2> An embodiment of the composition containing the polymer (A), the acid diffusion control agent (B-2), and a solvent (D).

The radiation-sensitive composition of the embodiment <1> may further contain the acid diffusion control agent (B-2). Also, the radiation-sensitive composition of the embodiment <1> or <2> may further contain an additional component other than those described in relation to the above embodiments. For example, the radiation-sensitive composition of the embodiment <1> may further contain a compound which differs from the acid-generator (B) and which can generate an acid weaker than the acid-generating agent (B-1) in the present composition through exposure to the radiation (hereinafter may also be referred to as an “additional acid diffusion control agent” or an “acid diffusion control agent (C-2)”). Also, the radiation-sensitive composition of the embodiment <2> may further contain a compound which differs from the acid-generator (B) and which can generate an acid stronger than the acid diffusion control agent (B-2) in the present composition through exposure to the radiation (hereinafter may also be referred to as an “additional acid-generating agent” or an “acid-generating agent (C-1)”). Specifically, the composition includes the following embodiments <1-1> and <2-1>:
<1-1> An embodiment of the composition containing the polymer (A), the acid-generating agent (B-1), the acid diffusion control agent (C-2), and the solvent (D); and
<2-1> An embodiment of the composition containing the polymer (A), the acid diffusion control agent (B-2), the acid-generating agent (C-1), and the solvent (D).

The radiation-sensitive compositions of the aforementioned embodiments <1-1> and <2-1> are particularly preferred, since high sensitivity and CDU performance can be achieved in a well-balanced manner. Further examples of the suitable component to be contained in the present composition include a high-fluorine content polymer (E) other than the aforementioned components. Hereinafter, these components will next be described in detail. Notably, in the present specification, the additional acid-generating agent and the additional acid diffusion control agent may also be referred to collectively as an “additional acid-generator (C)”.

### <(A) Polymer>

The polymer (A) is a component forming a base resin of the present composition. As the polymer (A), there is preferably used a polymer which includes at least one species selected from the group consisting of a structural unit (i.e., a constitutional unit) having an acid-releasable group (hereinafter may also be referred to as a “structural unit (I)”) and a structural unit having a hydroxy group bound to an aromatic ring (hereinafter may also be referred to as a “structural unit (II)”). The polymer (A) may be formed of a single species or two or more species. The term “structural unit” refers to a unit mainly forming a main chain structure and is a unit forming two or more chemical structures included at least in the main chain structure.

Structural unit (I)

The acid-releasable group present in the structural unit (I) is a group which can substitute a hydrogen atom of an acidic group such as a carboxy group or a hydroxy group and which is eliminated by the action of acid. When a polymer having an acid-releasable group is incorporated into the present composition, the acid-releasable group is released from the present composition via exposure to the radiation to thereby form an acidic group, which modifies the solubility of the polymer component(s) in a developer. As a result, excellent lithographic characteristics can be imparted to the present composition, to thereby form a suitable resist pattern.

No particular limitation is imposed on the structural unit (I), so long as the unit has an acid-releasable group. Examples of the structural unit (I) include structural units represented by the below-described formula (i-1) (hereinafter may also be referred to as “structural units (I-1)” and structural units represented by the below-described formula (i-2) (hereinafter may also be referred to as “structural units (I-2)”).

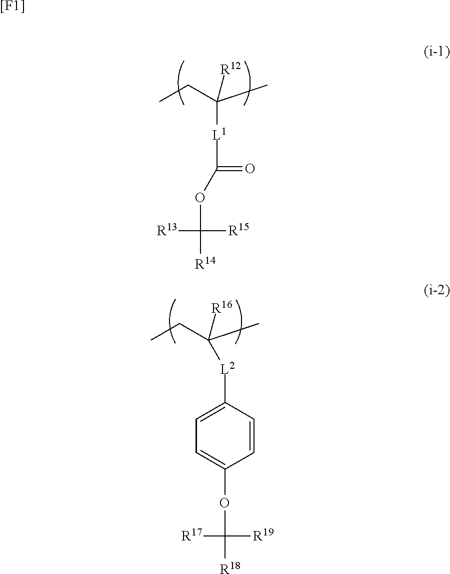

(In the formula (i-1), R¹² represents a hydrogen atom, a fluoro group, a methyl group, or a trifluoromethyl group; L¹ represents a single bond, a substituted or unsubstituted phenylene group, or *¹—CO—O—R¹⁰—. R¹⁰ represents a C1 to C6 substituted or unsubstituted alkanediyl group, or a divalent group formed by inserting —O—, —CO—, or —COO— to a carbon-carbon bond of the C2 to C6 alkanediyl group; “*¹” represents a chemical bond to be linked to a carbon atom to which R¹² is bonded; R¹³ represents a C1 to C20 monovalent hydrocarbon group; each of R¹⁴ and R¹⁵ independently represents a C1 to C20 monovalent hydrocarbon group, or R¹⁴ and R¹⁵ are linked to form a C3 to C20 alicyclic structure including the carbon atom to which R¹⁴ and R¹⁵ are bound; and hydrogen atoms of each of R¹³, R¹⁴, and R¹⁵ may be at least partially substituted with a halogen atom or an alkoxy group; and
in the formula (i-2), R¹⁶ represents a hydrogen atom, a fluoro group, a methyl group, or a trifluoromethyl group; L² represents a single bond, an ether bond, an ester bond, or an amide bond; each of R¹⁷, R¹⁸, and R¹⁹ independently represents a hydrogen atom, a C1 to C20 monovalent hydrocarbon group, or a C1 to C20 monovalent oxyhydrocarbon group; hydrogen atoms of each of R¹⁷, R¹⁸, and R¹⁹ may be at least partially substituted with a halogen atom or an alkoxy group).

In the aforementioned formula (i-1) or (i-2), R¹² is preferably a hydrogen atom or a methyl group, more preferably a methyl group, from the viewpoint of co-polymerizability of a monomer providing the structural unit (1-1), and R¹⁶ is preferably a hydrogen atom or a methyl group, more preferably a hydrogen atom, from the viewpoint of co-polymerizability of a monomer providing the structural unit (I-2).

When L¹ is *¹—CO—O—R¹⁰—, examples of the C1 to C6 alkanediyl group represented by R¹⁰ include a methanediyl group, a 1,2-ethanedily group, a 1,2-propanediyl group, and a 1,3-propanediyl group. Examples of the substituent in L¹ include a halogen atom.

L² is preferably a single bond, an ester bond, or an amide bond (—CO—NH—), more preferably a single bond or an ester bond.

Examples of the C1 to C20 monovalent hydrocarbon group represented by each of R¹³ to R¹⁵ and R¹⁷ to R¹⁹ include a C1 to C20 monovalent chain hydrocarbon group, a C3 to C20 monovalent alicyclic hydrocarbon group, and a C6 to C20 monovalent aromatic hydrocarbon group. Examples of the C1 to C20 monovalent chain hydrocarbon group include alkyl groups such as methyl, ethyl, n-propyl, i-propyl, n-butyl, i-butyl, sec-butyl, t-butyl, and pentyl; alkenyl groups such as ethenyl, propenyl, butenyl, and pentenyl; and alkynyl groups such as ethynyl, propynyl, butynyl, and pentynyl.

Examples of the C3 to C20 monovalent alicyclic hydrocarbon group include monocyclic alicyclic saturated hydrocarbon groups such as cyclopropyl, cyclobutyl, cyclopentyl, and cyclohexyl; polycyclic alicyclic saturated hydrocarbon groups such as norbornyl, adamantyl, tricyclodecyl, and tetracyclododecyl; monocyclic alicyclic unsaturated hydrocarbon groups such as cyclopropenyl, cyclobutenyl, cyclopentenyl, and cyclohexenyl; and polycyclic alicyclic saturated hydrocarbon groups such as norbornenyl and tricyclodecenyl.

Examples of the C6 to C20 monovalent aromatic hydrocarbon group include aryl groups such as phenyl, tolyl, xylyl, naphthyl, and anthryl; and aralkyl groups such as benzyl, phenethyl, naphtylmethyl, and anthrylmethyl.

Examples of the C3 to C20 alicyclic structure formed with the carbon atom to which R¹⁴ and R¹⁵ are bound, the structure being formed by linking R¹⁴ and R¹⁵, include monocyclic alicyclic structures such as a cyclopropane structure, a cyclobutane structure, a cyclopentane structure, a cyclohexane structure, a cycloheptane structure, and a cyclooctane structure; and polycyclic alicyclic structures such as a norbornane structure, an adamantane structure, a tricyclodecane structure, and a tetracyclododecane structure.

Examples of the C1 to C20 monovalent oxyhydrocarbon group represented by any of R¹⁷, R¹⁸, and R¹⁹ include groups formed by incorporating an oxygen atom into the chemical bond side end of any of the C1 to C20 monovalent hydrocarbon groups represented by the aforementioned R¹³ to R¹⁵ and R¹⁷ to R¹⁹ (e.g., an alkyloxy group, a cycloalkyloxy group, and an aryloxy group), as exemplified above.

Among them, R¹⁷, R¹⁸, and R¹⁹ are preferably a chain hydrocarbon group and a cycloalkyloxy group.

Specific examples of the structural unit (I-1) include structural units represented by the following formulas.

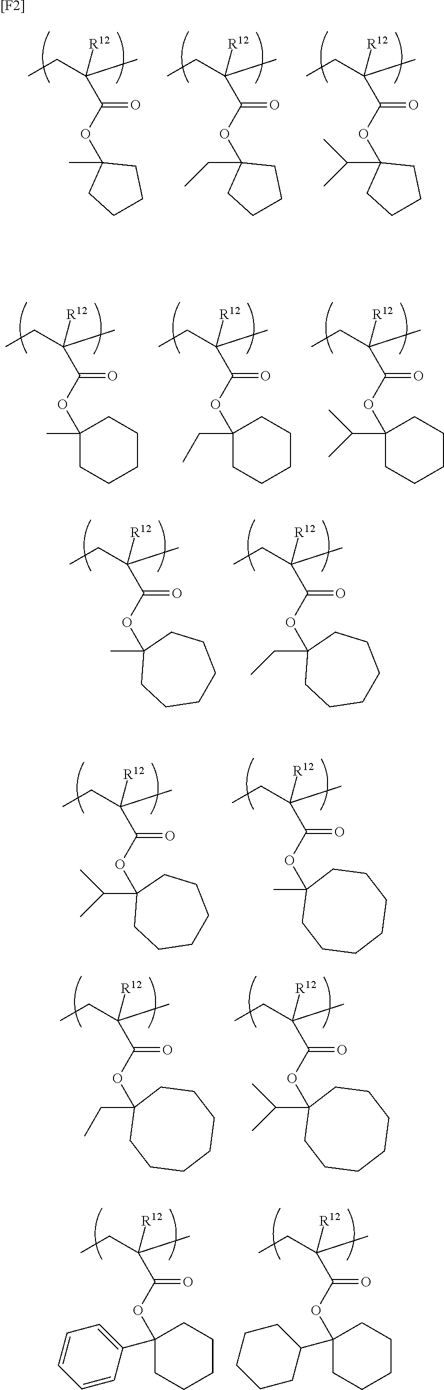

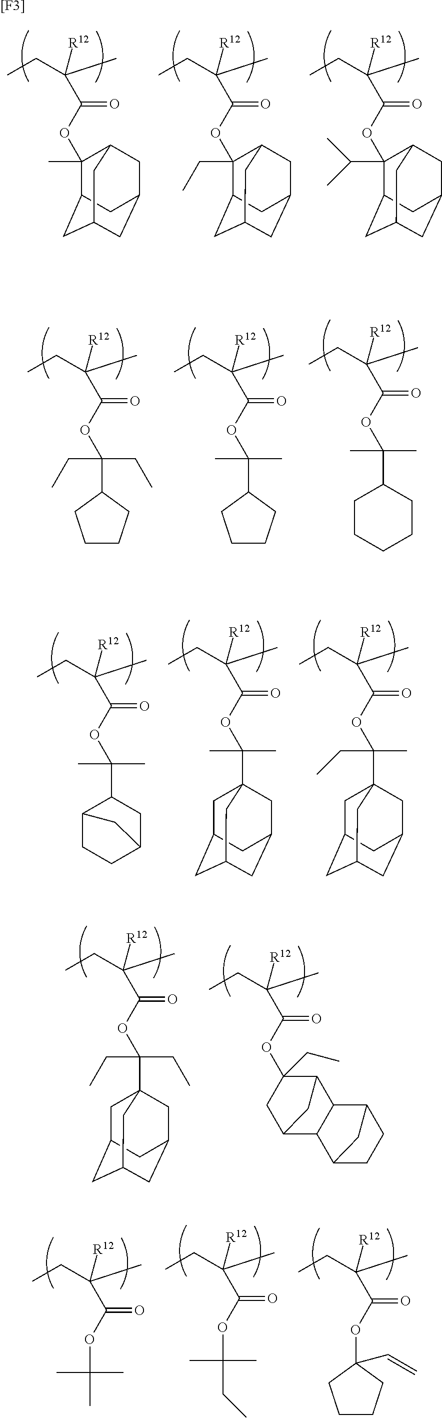

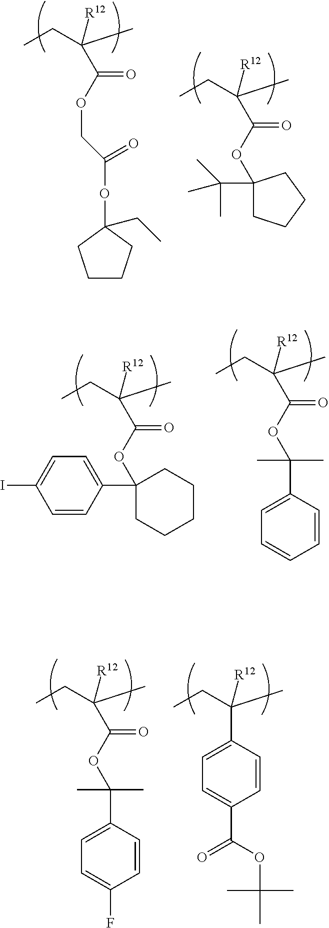

(In the above formulas, R¹² represents a hydrogen atom, a fluorine atom, a methyl group, or a trifluoromethyl group.)

Specific examples of the structural unit (I-2) include structural units represented by the following formulas.

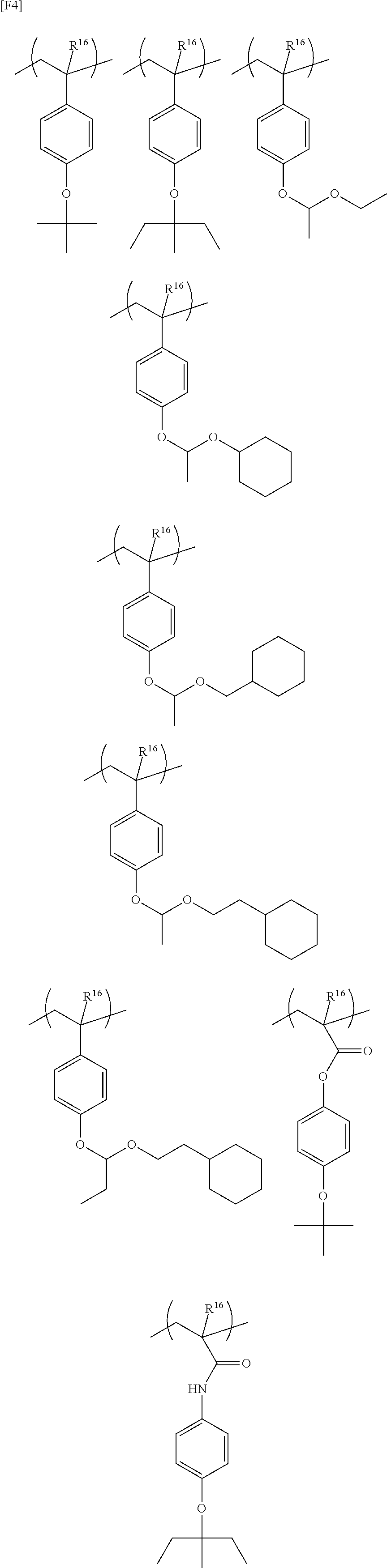

(In the above formulas, R¹⁶ represents a hydrogen atom, a fluorine atom, a methyl group, or a trifluoromethyl group.)

The relative amount of the structural unit (I) in all the structural units forming the polymer (A) is preferably 20 mol % or more, more preferably 30 mol % or more, still more preferably 35 mol % or more. Also, the relative amount of the structural unit (I) in all the structural units forming the polymer (A) is preferably 80 mol % or less, more preferably 70 mol % or less, still more preferably 65 mol % or less. Adjusting the structural unit (I) content to satisfy the aforementioned conditions is preferred, since considerable difference in dissolution rate with respect to a developer between the radiation-exposed part and the radiation-unexposed part can be sufficiently attained, whereby favorable resist film pattern can be provided.

Structural unit (II)

The structural unit (II) is a structural unit having a hydroxy group bound to an aromatic ring. Examples of the aromatic ring include a benzene ring, a naphthalene ring, and an anthracene ring. Of these, a benzene ring and a naphthalene ring are preferred, with a benzene ring being more preferred. No particular limitation is imposed on the number of the hydroxy group(s) bound to the aromatic ring in the structural unit (II). The number of the hydroxy group(s) bound to the aromatic ring is preferably 1 to 3, more preferably 1 or 2. Examples of the structural unit (II) include the structural units represented by the following formula (ii).

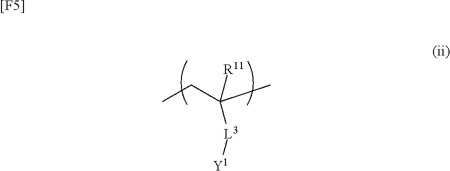

(In the formula (ii), R¹¹ represents a hydrogen atom, a fluoro group, a methyl group, or a trifluoromethyl group; L³ represents a single bond, an ether bond, a carbonyl group, an ester bond, or an amide bond; and Y¹ represents a monovalent group having a hydroxy group bonded to an aromatic ring.)

In the above formula (ii), R¹¹ is preferably a hydrogen atom or a methyl group, and L³ is preferably a single bond or an ester bond, from the viewpoint of co-polymerizability of a monomer to form the structural unit (II).

Specific examples of the structural unit (II) include the structural units represented by the following formulas.

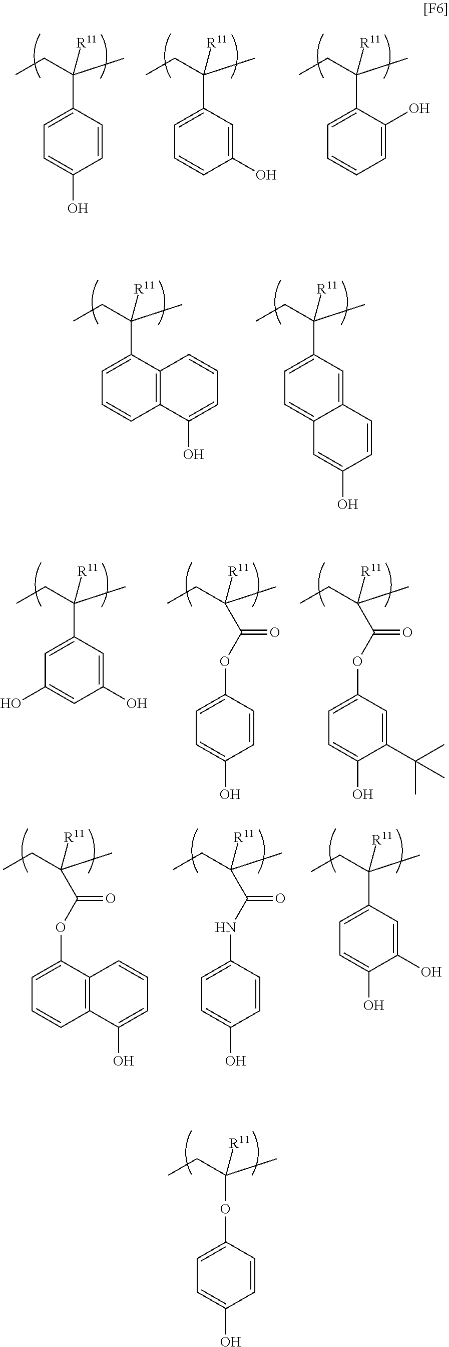

(In the above formulas, R¹¹ represents a hydrogen atom, a fluoro group, a methyl group, or a trifluoromethyl group.)

The relative amount of the structural unit (II) in all the structural units forming the polymer (A) is preferably 5 mol % or more, more preferably 10 mol % or more, still more preferably 15 mol % or more. Also, the relative amount of the structural unit (II) in all the structural units forming the polymer (A) is preferably 90 mol % or less, more preferably 80 mol % or less, still more preferably 60 mol % or less. By adjusting the structural unit (II) content to satisfy the above conditions, lithographic characteristics of the present composition can be further enhanced, which is preferred.

In the case where a polymer including the structural unit (II) is produced as the polymer (A), the structural unit (II) may be prepared by conducting polymerization while a phenolic hydroxy group is protected by a protective group such as an alkali-releasable group during polymerization, and then conducting deprotection through hydrolysis.

The polymer (A) may include a polymer having a structural unit (II), in addition to a polymer having a structural unit (I). In this case, specific embodiments of the present composition include a polymer composition containing a polymer having a structural unit (I) but no structural unit (II), and a polymer having a structural unit (II) and no structural unit (I); and a polymer composition containing a polymer having both a structural unit (I) and a structural unit (II), and a polymer having a structural unit (II) but no structural unit (I). From the viewpoint of yielding a radiation-sensitive composition exhibiting excellent lithographic characteristics (e.g., line width roughness) (LWR) performance and CDU performance) and failure suppression property, the present composition preferably contains, as the polymer (A), a polymer composition containing a polymer having both a structural unit (I) and a structural unit (II).

The polymer (A) may further include a structural unit differing from the structural units (I) and (II) (hereinafter may also be referred to as an “additional structural unit”). Examples of the additional structural unit include the below-mentioned structural units (III) to (V):
Structural unit (III): a structural unit including a radiation-sensitive onium cation and an organic anion;
Structural unit (IV): a structural unit having a cyclic structure of a lactone structure, a cyclic carbonate structure, a sultone structure, or a combined structure of two or more of them; and
Structural unit (V): a structural unit having an alcoholic hydroxy group.
   Structural unit (III)

The structural unit (III) is typically a structural unit derived from an onium salt having a group involved in polymerization (preferably, a polymerizable carbon-carbon unsaturated bond-containing group). By virtue of the presence of the structural unit (III) in the polymer (A), the effect of reducing development residue can be enhanced.

Specific examples of the structural unit (III) include a structural unit represented by the following formula (iii-1), a structural unit represented by the following formula (iii-2), and a structural unit represented by the following formula (iii-3).

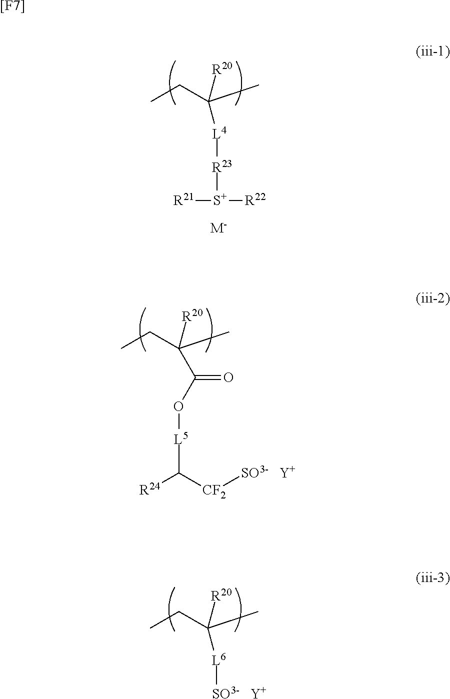

(In the formula (iii-1), R²⁰ represents a hydrogen atom or a methyl group; L⁴ represents a single bond, —O—, or —COO—; R²³ represents a C1 to C6 substituted or unsubstituted alkanediyl group, a C2 to C6 substituted or unsubstituted alkenediyl group, or a C6 to C12 substituted or unsubstituted arylene group; each of R²¹ and R²² independently represents a C1 to C12 substituted or unsubstituted alkyl group, a C2 to C12 substituted or unsubstituted alkenyl group, or a C6 to C20 substituted or unsubstituted aryl group; and M-represents an anion;

in the formula (iii-2), R²⁰ represents a hydrogen atom or a methyl group; L⁵ represents a single bond, —R^{30a}13 CO—O—, —R^{30a}—O—, or —R^{30a}—O—CO—; R³⁰ represents a C1 to C20 substituted or unsubstituted divalent hydrocarbon group or a divalent group formed by inserting —O—, —CO—, or —COO— to a carbon-carbon bond of the hydrocarbon group; R²⁴ represents a hydrogen atom, a C1 to C10 alkyl group, or a C1 to C10 fluoroalkyl group; and Y⁺ represents an onium cation represented by the following formula (Y-1) or (Y-2); and
in the formula (iii-3), R²⁰ represents a hydrogen atom or a methyl group; L⁶ represents a single bond, a C1 to C6 substituted or unsubstituted alkanediyl group, a C2 to C6 substituted or unsubstituted alkenediyl group, a C6 to C12 substituted or unsubstituted arylene group, —CO—O—R^{30b}—, or —CO—NH—R^{30b}—; R^{30b} represents a C1 to C6 substituted or unsubstituted alkanediyl group or a divalent group formed by inserting —O—, —CO—, or —COO— to a carbon-carbon bond of the C2 to C6 alkanediyl group; and Y⁺ represents an onium cation represented by the following formula (Y-1) or (Y-2).)

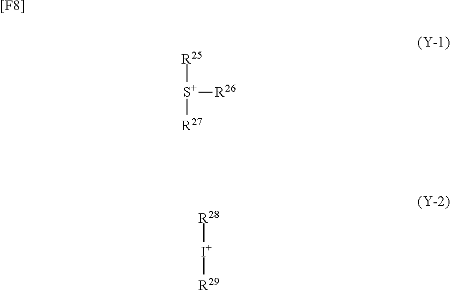

(In the formulas (Y-1) and (Y-2), each of R²⁵ to R²⁹ independently represents a C1 to C12 substituted or unsubstituted alkyl group, a C2 to C12 substituted or unsubstituted alkenyl group, or a C6 to C20 substituted or unsubstituted aryl group.)

In formulas (iii-1) to (iii-3), (Y-1), and (Y-2), when any of the groups R²¹ to R²³, and R²⁵ to R²⁹ has a substituent, examples of the substituent include a fluoro group, a chloro group, a bromo group, an iodo group, an alkoxy group, a cycloalkyloxy group, an ester group, an alkylsulfonyl group, a cycloalkylsulfonyl group, a hydroxy group, a carboxy group, a cyano group, a nitro group, an acetyl group, and a fluoroacetyl group.

In these formulas, the cation preferably has a triarylsulfonium cation structure or a diaryliodonium cation structure.

Specific examples of the structural unit (III) include structural units represented by the following formulas (iii-1a) to (iii-10a).

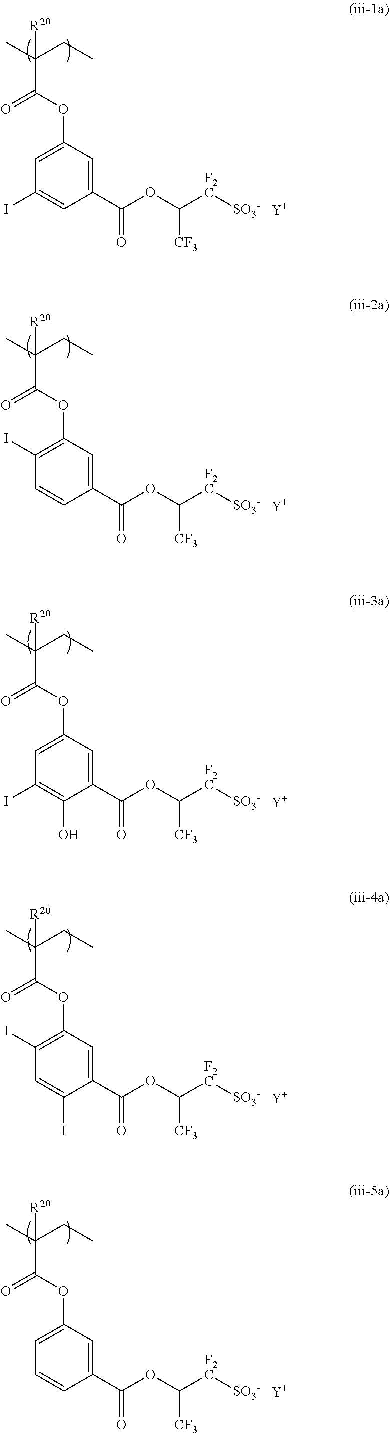

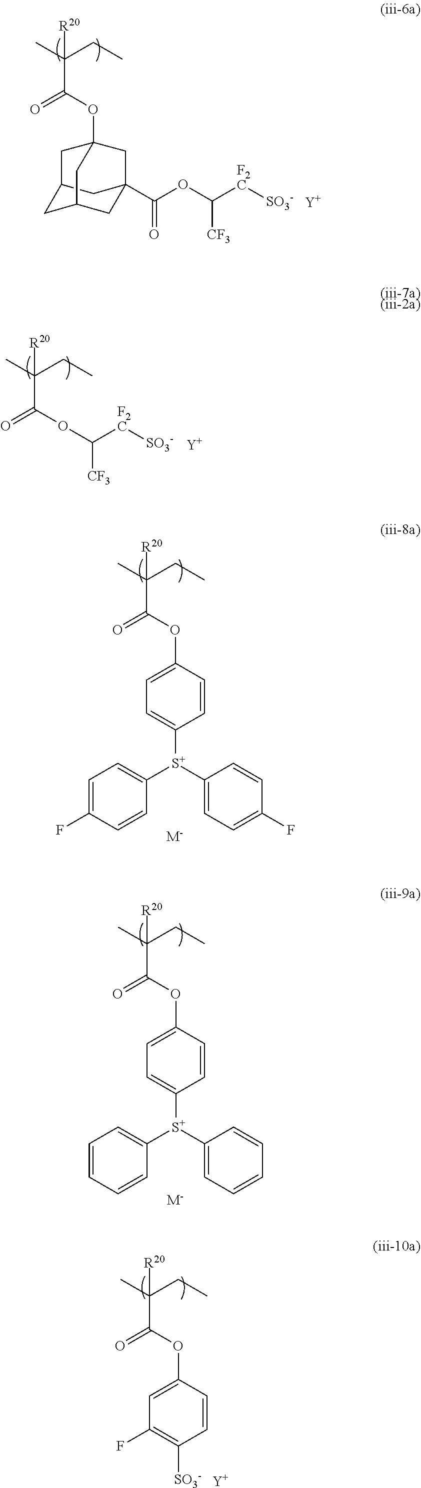

(In the formulas (iii-1a) to (iii-10a), R²⁰ represents a hydrogen atom or a methyl group; Y⁺ represents an onium cation represented by the following formula (Y-1) or (Y-2); and M⁻ represents an anion.)

When the polymer (A) includes the structural unit (III), the relative amount of structural unit (III) in all the structural units forming the polymer (A) is preferably 1 mol % or more, more preferably 3 mol % or more, still more preferably 5 mol % or more. Also, the relative amount of structural unit (III) in all the structural units forming the polymer (A) is preferably 50 mol % or less, more preferably 40 mol % or less, still more preferably 30 mol % or less. Adjusting of the structural unit (III) content to satisfy the above conditions is preferred, since a drop in resolution involved in diffusion of acid can be suppressed, whereby the lithographic characteristics of the present composition can be further enhanced.

Structural unit (IV)

The structural unit (IV) has at least one structure selected from the group consisting of a lactone structure, a cyclic carbonate structure, and a sultone structure (except for structural units corresponding to structural unit (I) to (III)). Through incorporation of the structural unit (IV) into the polymer (A), solubility of the composition in a developer can be controlled, and there can be improved close adhesion between a substrate and a resist film formed from the present composition.

Examples of the structural unit (IV) includes the structural units represented by the following formulas.

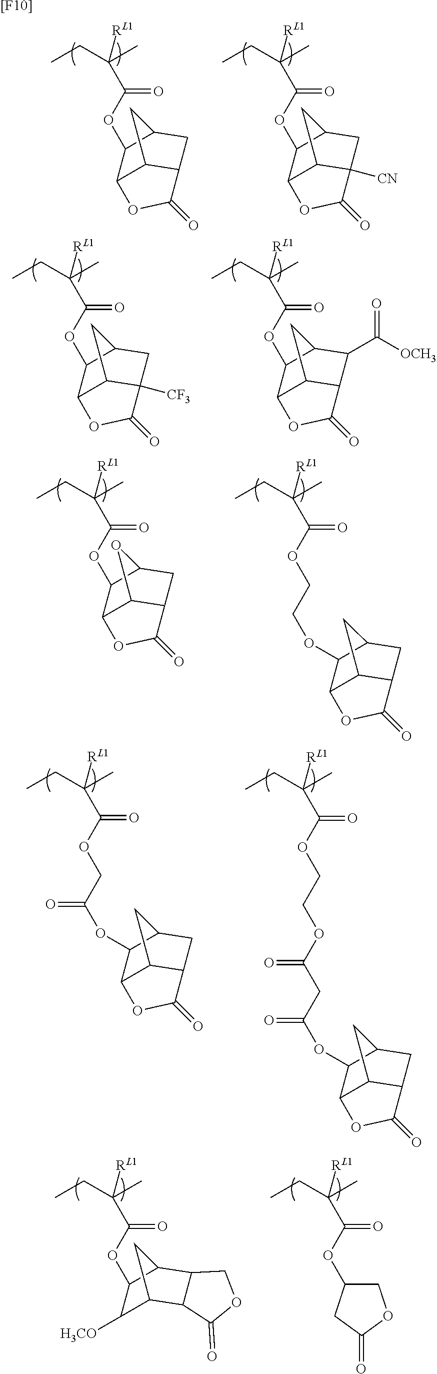

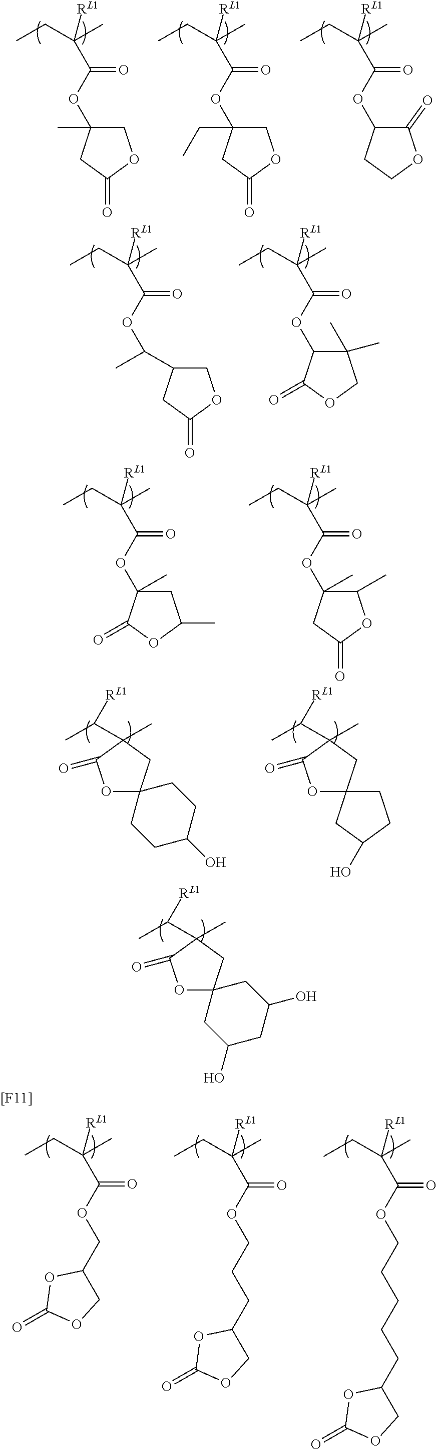

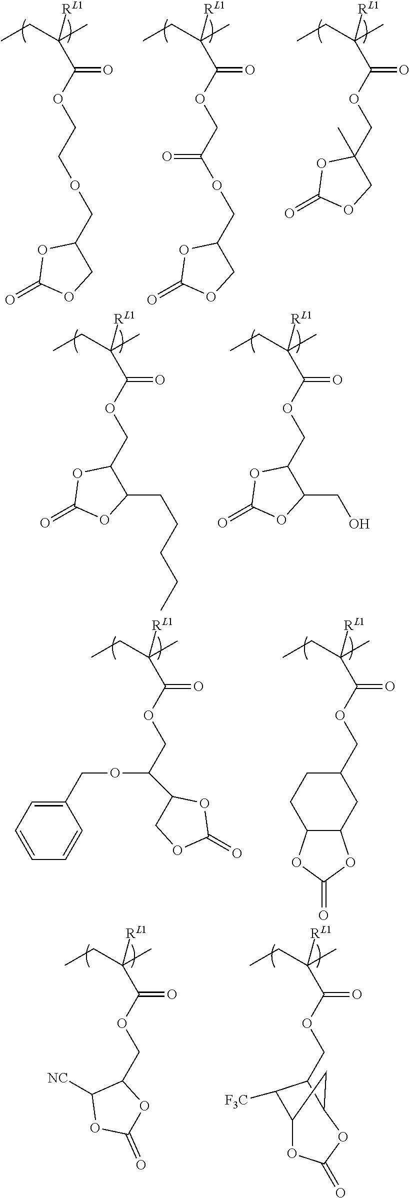

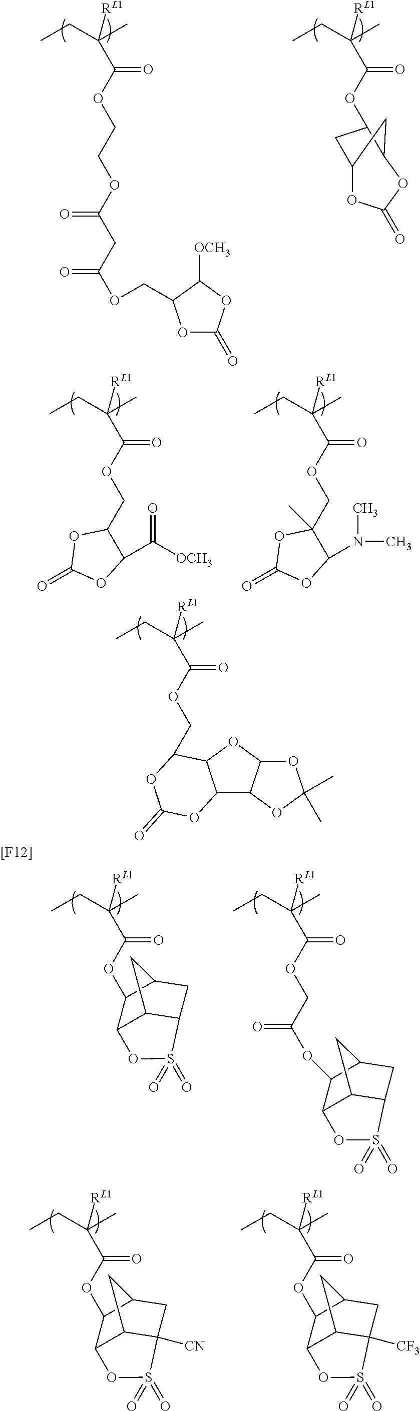

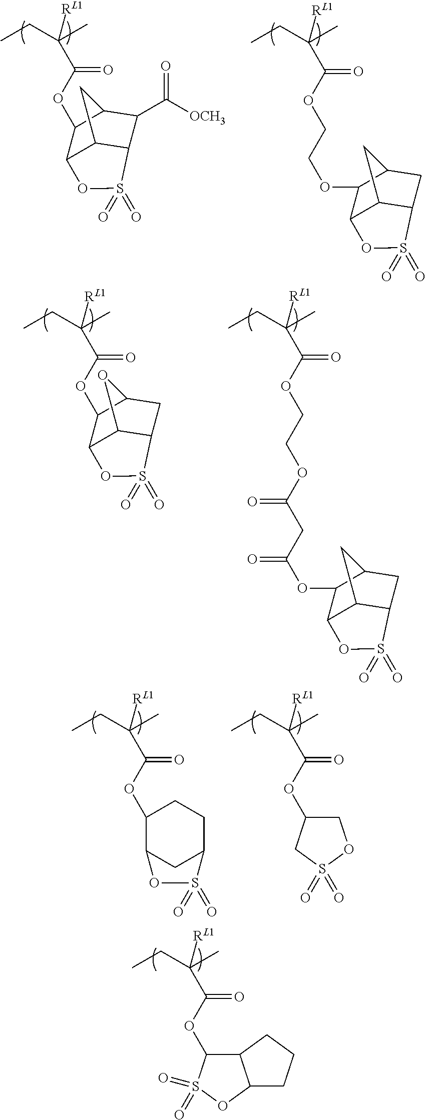

(In the above formulas, R^{L1} represents a hydrogen atom, a fluoro group, a methyl group, or a trifluoromethyl group.)

When the polymer (A) includes the structural unit (IV), the relative amount of structural unit (IV) in all the structural units forming the polymer (A) is preferably 5 mol % or more, more preferably 10 mol % or more. Also, the relative amount of structural unit (IV) in all the structural units forming the polymer (A) is preferably 50 mol % or less, more preferably 40 mol % or less. By adjusting the structural unit (IV) content to satisfy the aforementioned conditions, there can be enhanced the lithographic characteristics of the present composition, and close adhesion between a substrate and a resist film formed from the present composition.

Structural unit (V)

The structural unit (V) is a structural unit having an alcoholic hydroxy group (except for a structural unit corresponding to the structural units (I) to (IV)). As used herein, the term “alcoholic hydroxy group” refers to a group having a structure in which a hydroxy group is directly bound to an aliphatic hydrocarbon group. The aliphatic hydrocarbon group may be a chain hydrocarbon group or an alicyclic hydrocarbon group. By incorporating the structural unit (V) into the polymer (A), solubility of the polymer in a developer can be improved, whereby lithographic characteristics of the present composition can be further improved. Specific examples of the monomer for providing the structural unit (V) include 3-hydroxyadamantan-1-yl (meth)acrylate and 2-hydroxyethyl (meth)acrylate.

When the polymer (A) includes the structural unit (V), the relative amount of structural unit (V) in all the structural units forming the polymer (A) is preferably 1 mol % or more, more preferably 3 mol % or more. Also, the relative amount of structural unit (V) in all the structural units forming the polymer (A) is preferably 30 mol % or less, more preferably 15 mol % or less.

In addition to the aforementioned structural units, examples of the structural unit of the polymer (A) include a structural unit having a cyano group, a nitro group, or a sulfonamide group (e.g., a structural unit derived from 2-cyanomethyladamantan-2-yl (meth)acrylate); a structural unit having a halogen atom (e.g., a structural unit derived from 2,2,2-trifluoroethyl (meth)acrylate, a structural unit derived from 1,1,1,3,3,3-hexafluoropropan-2-yl (meth)acrylate, or a structural unit derived from 4-iodostyrene); and a structural unit having a non-acid-releasable hydrocarbon group (e.g., a structural unit derived from styrene, a structural unit derived from vinylnaphthalene, a structural unit derived from n-pentyl (meth)acrylate, or a structural unit derived from indene). The relative amount of any of these structural units may be appropriately set in accordance with the type of each structural unit, so long as the effects of the present disclosure are not impaired.

The polymer (A) content of the present composition (the total amount when two more polymers (A) are included), with respect to the total solid content of the present composition, is preferably 50 mass % or more, more preferably 70 mass % or more, still more preferably 80 mass % or more. Also, the polymer (A) content with respect to the total solid content of the present composition is preferably 99 mass % or less, more preferably 98 mass % or less, still more preferably 95 mass % or less. By adjusting the polymer (A) content to satisfy the aforementioned conditions, suitable resist patterns can be formed. As used herein, the term “total solid content” refers to the sum of the relative amounts of the components other than the solvent (D). The polymer (A) may be synthesized through, for example, polymerization of monomers for providing the corresponding structural units in an appropriate solvent by use of a radical polymerization initiator or the like.

The weight average molecular weight (Mw) of the polymer (A), which is determined through gel permeation chromatography (GPC) and is reduced to polystyrene, is preferably 1,000 or more, more preferably 2,000 or more, still more preferably 3,000 or more, particularly preferably 5,000 or more. Also, the Mw is preferably 50,000 or less, more preferably 30,000 or less, still more preferably 20,000 or less, particularly preferably 10,000 or less. Adjusting the Mw of the polymer (A) so as to satisfy the above conditions is preferred, since coatability of the present composition can be improved, and development failure can be sufficiently suppressed.

The ratio (Mw/Mn) of Mw to the number average molecular weight (Mn) of the polymer (A), which is determined through GPC and is reduced to polystyrene, is preferably 5.0 or less, more preferably 3.0 or less, still more preferably 2.0 or less. Also, the Mw/Mn of the polymer [A] is generally 1 or more, preferably 1.3 or more.

### <(B) Acid-Generator>

Next will be described an acid-generating agent (B-1) and an acid diffusion control agent (B-2), which are specific embodiments of the acid-generator (B).

Acid-generating agent (B-1)
(Onium cation)

No particular limitation is imposed on the onium cation included in the acid-generating agent (B-1) (i.e., particular cation), so long as the cation is a radiation-sensitive onium cation having one or more groups Rf¹s. The particular cation preferably has, among others, a sulfonium cation structure or an iodonium cation structure.

When the particular cation has a fluoroalkyl group as group Rf¹, the fluoroalkyl group may be linear-chain or branched. The fluoroalkyl group serving as group Rf¹ is preferably a C1 to C10 group, and examples thereof include trifluoromethyl, 2,2,2-trifluoroethyl, perfluoroethyl, 2,2,3,3,3-pentafluoropropyl, 2,2,2-trifluoro-1-(trifluoromethyl)ethyl, perfluoro-n-propyl, perfluoroisopropyl, perfluoro-n-butyl, perfluoroisobutyl, perfluoro-t-butyl, 2,2,3,3,4,4,5,5-octafluoropentyl, and perfluorohexyl. Of these, a C1 to C5 is preferred, with trifluoromethyl, 2,2,2-trifluoroethyl, or perfluoroethyl being more preferred, trifluoromethyl being still more preferred.

From the viewpoint of sensitivity, group Rf¹ is preferably at least one member selected from the group consisting of a fluoro group, a trifluoromethyl group, a 2,2,2-trifluoroethyl group, and a perfluoroethyl group, with a fluoro group or a trifluoromethyl group being more preferred.

The number of groups Rf¹s present in the particular cation is preferably 2 or more, more preferably 3 or more, from the viewpoint of further enhancing the CDU performance and sensitivity of the present composition. Also, from the viewpoint of achieving the balance between the effect of enhancing sensitivity and ease of synthesis, the number of groups Rf¹s present in the particular cation is preferably 10 or less, more preferably 8 or less, still more preferably 7 or less, yet more preferably 6 or less.

When the particular cation has a fluoroalkyl group as group Rf¹, the number of fluoroalkyl groups in the particular cation corresponds to the number of groups Rf¹s present in the particular cation. Thus, in the case where the particular cation has two trifluoromethyl groups (—CF₃), the number of groups Rf¹s present in the particular cation is 2. In the case where the particular cation has one fluoro group (—F) bound to an aromatic ring and two trifluoromethyl groups (—CF₃), the number of groups Rf¹s present in the particular cation is 3.

No particular limitation is imposed on the bonding position of group Rf¹ in the particular cation. From the viewpoint of a high effect of improving sensitivity of the present composition, one or more groups Rf¹s present in the particular cation are preferably bound directly to an aromatic ring present in the particular cation. More preferably, two or more groups Rf¹s present in the particular cation are bound directly to the aromatic ring. When the particular cation has two or more groups R^{f1}s, the two or more groups Rf¹s may be bound to a single aromatic ring or to different aromatic rings in the particular cation.

Particularly preferably, the particular cation has one or more aromatic rings each bound to a sulfonium cation or an iodonium cation (hereinafter may also be referred to as “aromatic rings Ar¹s), and group Rf¹ is directly bound to any aromatic ring Ar¹.

Examples of the aromatic ring Ar¹ include a benzene ring, a naphthalene ring, and an anthracene ring. Among the above cases, the aromatic ring Ar¹ is preferably a benzene ring or a naphthalene ring, particularly preferably a benzene ring. In the particular cation, the same description as mentioned in relation to the number of groups Rf¹s in the particular cation is applied to the total number of groups Rf¹s bound to an aromatic ring Ar¹. Thus, the total number of groups Rf¹s bound to an aromatic ring Ar¹ is preferably 2 or more, more preferably 3 or more. Also, from the viewpoint of achieving the balance between the effect of enhancing sensitivity and ease of synthesis, the total number of groups Rf¹s bound to an aromatic ring Ar¹ is preferably 10 or less, more preferably 8 or less, still more preferably 7 or less, yet more preferably 6 or less. When the total number of groups Rf¹s bound to an aromatic ring Ar¹ is 2 or more, the two or more groups Rf¹s may be bound to a single aromatic ring or to different aromatic rings in the particular cation.

From the viewpoint of sensitivity, the particular cation preferably has a triarylsulfonium cation structure or a diaryliodonium cation structure. Specifically, the particular cation is preferably any of the cations represented by the following formula (1) or (2).

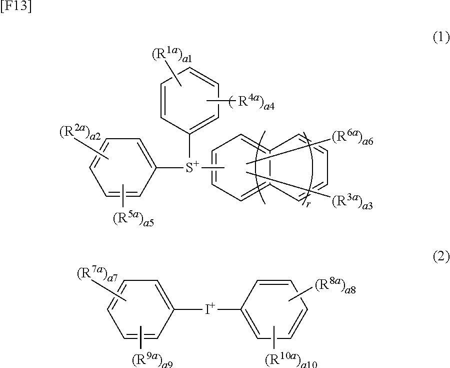

(In the formula (1), each of R^{1a}, R^{2a}, and R^{3a} independently represents a fluoro group or a fluoroalkyl group; each of R^{4a} and R^{5a} independently represents a monovalent substituent, or R^{4a} and R^{5a} are combined to form a single bond or a divalent group which links the rings to which R^{4a} and R^{5a} are bound; R^{6a} is a monovalent substituent; each of a1, a2, and a3 is independently an integer of 0 to 5, with a1+a2+a3≥1 being satisfied; each of a4, a5, and a6 is independently an integer of 0 to 3; r is 0 or 1, with a1+a4≤5, a2+a5≤5, and a3+a6≤2×r+5 being satisfied; and
in the formula (2), each of R^{7a} and R^{8a} independently represents a fluoro group or a fluoroalkyl group; each of R^{9a} and R^{10a} independently represents a monovalent substituent; each of a7 and a8 is independently an integer of 0 to 5, with a7+a8≥1 being satisfied; each of a9 and a10 is independently an integer of 0 to 3, with a7+a9≤5 and a8+a10≤5 being satisfied.)

In the aforementioned formulas (1) and (2), specific examples including preferred members of fluoroalkyl groups represented by R^{1a}, R^{2a}, R^{3a}, R^{7a}, and R^{8a} include the same groups as mentioned in relation to the cases where the particular cation has a fluoroalkyl group as group Rf¹.

Among the aforementioned members, each of R^{1a}, R^{2a}, R^{3a}, R^{7a}, and R^{8a} is preferably a fluoro group, a trifluoromethyl group, a 2,2,2-trifluoroethyl group, or a perfluoroethyl group, more preferably a fluoro group or a trifluoromethyl group. By use of an onium salt having a structure in which a fluoro group or a trifluoromethyl group is directly bound to an aromatic ring present in a triarylsulfonium cation structure or a diaryliodonium cation structure, the sensitivity of the present composition can be further enhanced, and a composition exhibiting excellent CDU performance can be yielded.

In the aforementioned formulas (1) and (2), the monovalent substituents represented by R^{4a}, R^{5a}, R^{6a}, R^{9a}, and R^{10a} are groups differing from group Rf¹. Specific examples of the monovalent substituents represented by R^{4a}, R^{5a}, R^{6a}, R^{9a}, and R^{10a} include a chloro group, a bromo group, an iodo group, a substituted or unsubstituted alkyl group (excepting a fluoroalkyl group), a substituted or unsubstituted alkoxy group, a substituted or unsubstituted cycloalkyl group, a substituted or unsubstituted cycloalkyloxy group, an ester group, an alkylsulfonyl group, a cycloalkylsulfonyl group, a hydroxy group, a carboxy group, a cyano group, and a nitro

Regarding the alkyl group, alkoxy group, cycloalkyl group, and cycloalkyloxy group of R^{4a}, R^{5a}, R^{6a}, R^{9a}, and R^{10a}, the alkyl group is preferably a C1 to C5 linear-chain or branched-chain alkyl group, with methyl, ethyl, n-butyl, or t-butyl being more preferred. The alkoxy group is preferably a methoxy group, an ethoxy group, an n-propoxy group, or an n-butoxy group. The cycloalkyl group may be monocyclic or polycyclic. Of these, a cyclopentyl group or a cyclohexyl group is preferred. The cycloalkyloxy group is preferably a cyclopentyloxy group or a cyclohexyloxy group.

When any of the alkyl group, alkoxy group, or cycloalkyl group of R^{4a}, R^{5a}, R^{6a}, R^{9a}, and R^{10a} has a substituent, examples of the substituent include a chloro group, a bromo group, an iodo group, a hydroxy group, a carboxy group, a cyano group, a nitro group, and a C1 to C5 alkoxy group.

When any of R^{4a}, R^{5a}, R^{6a}, R^{9a}, and R^{10a} is an ester group (—COOR), examples of the hydrocarbon moiety (R) of the ester group include the same substituted or unsubstituted alkyl group and substituted or unsubstituted cycloalkyl groups as exemplified above. When any of R^{4a}, R^{5a}, R^{6a}, R^{9a}, and R^{10a} is an ester group, the ester group is preferably a methoxycarbonyl group, an ethoxycarbonyl group, or an n-butoxycarbonyl group.

When any of R^{4a}, R^{5a}, R^{6a}, R^{9a}, and R^{10a} is an alkylsulfonyl group, examples of the alkyl moiety forming the alkylsulfonyl group include the same substituted or unsubstituted alkyl group as exemplified above. When any of R^{4a}, R^{5a}, R^{6a}, R^{9a}, and R^{10a} is a cycloalkylsulfonyl group, examples of the alkyl moiety forming the cycloalkylsulfonyl group include the same substituted or unsubstituted cycloalkyl group as exemplified above.

When R^{4a} and R^{5a} are combined to form a divalent group which links the rings to which R^{10a} and R^{5a} are bound, examples of the divalent group include —COO—, —OCO—, —CO—, —O—, —SO—, —SO₂—, —S—, a C1 to C3 alkanediyl group, a C2 or C3 alkenediyl group, and a group formed by inserting —O—, —S—, —COO—, —OCO—, —CO—, —SO—, or —SO₂— into the carbon-carbon bond of an ethylene group. When R^{4a} and R^{5a} are combined to form a single bond or a divalent group which links the rings to which R^{4a} and R^{5a} are bound, R^{4a} and R^{5a} preferably form a single bond, —O—, or —S—.

The sum of a1, a2, and a3 is 1 or greater, preferably 2 or greater, more preferably 3 to 10, still more preferably 3 to 8. The sum of a7 and a8 is 1 or greater, more preferably 1 to 6.

Specific examples of the particular cation include, but are not limited to, the structures represented by the following formulas.

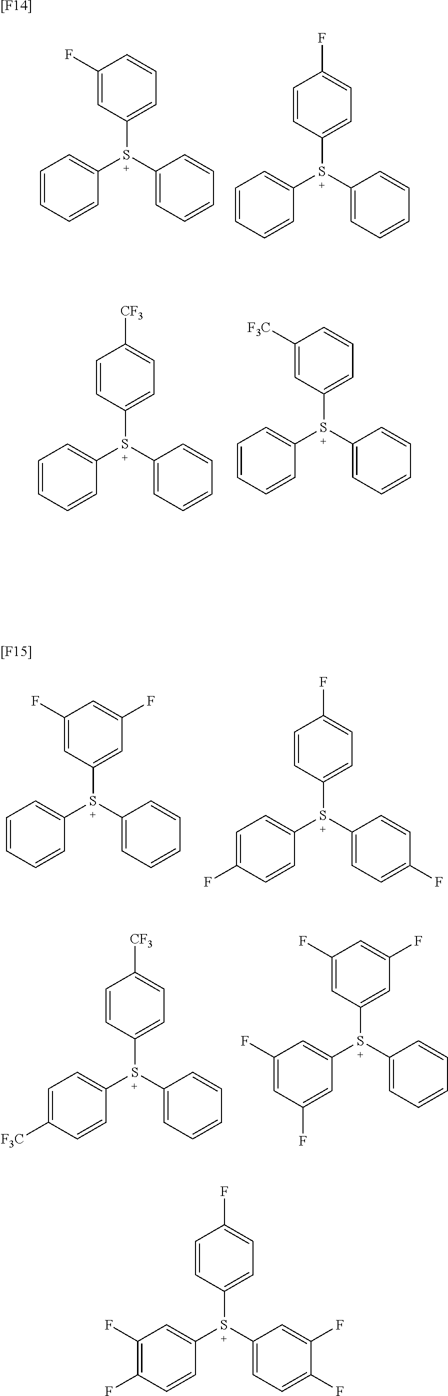

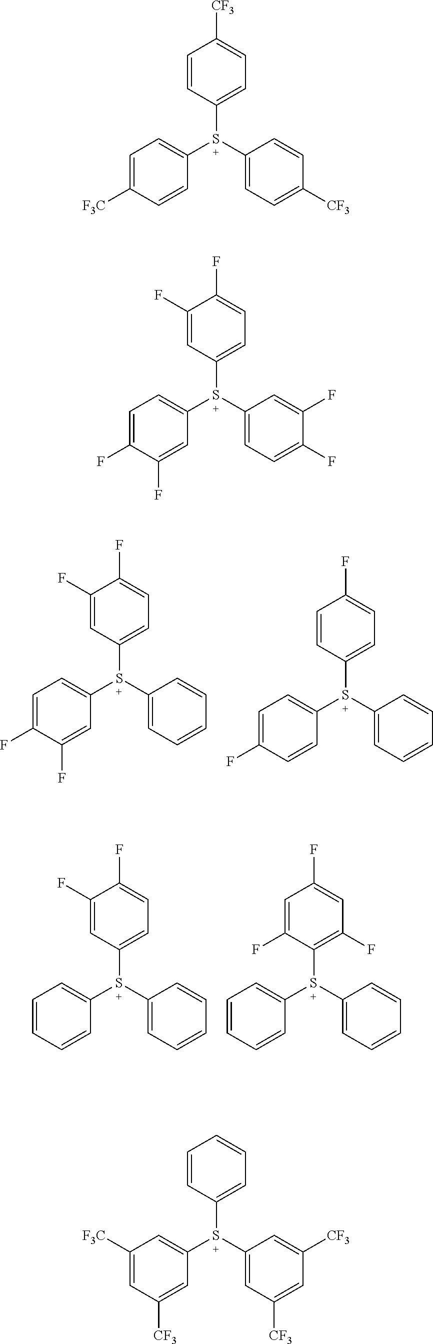

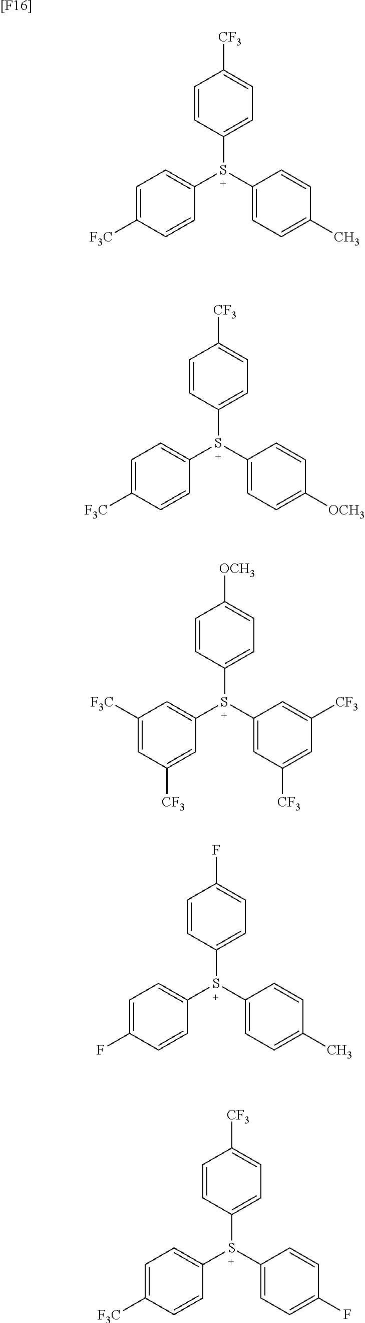

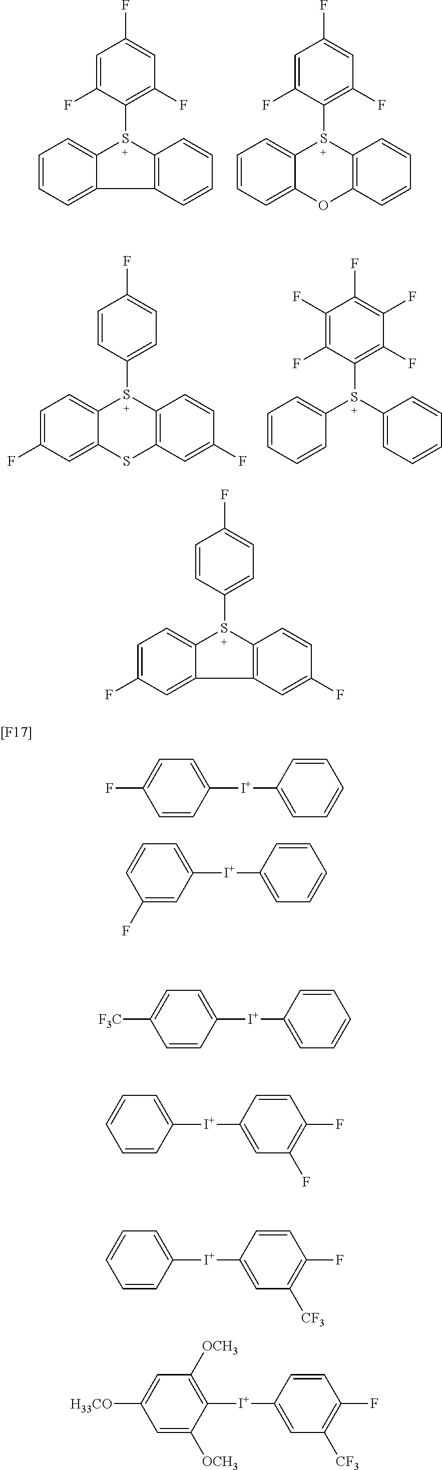

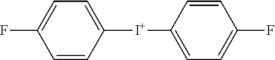 [SMILES: Fc1ccc([I+]c2ccc(F)cc2)cc1]

(Organic anion)

The organic anion included in the acid-generating agent (B-1) (hereinafter may also be referred to as a “particular anion AN1”) is, for example, a sulfonate anion structure, an imide anion structure, a methyl anion structure, a carboxylate anion structure, etc. Among them, the particular anion AN1 preferably has a sulfonate anion structure.

The number of iodo groups present in the particular anion AN1 is essentially 4 or greater. From the viewpoint of achieving high sensitivity and improved CDU performance of the present composition, the number of iodo groups present in the particular anion AN1 is preferably 5 or greater, more preferably 6 or greater. Also, from the viewpoint of achieving the balance between the effect of enhancing CDU performance and ease of synthesis, the number of iodo groups present in the particular anion AN1 is preferably 10 or smaller, more preferably 9 or smaller.

No particular limitation is imposed on the bonding position of the iodo groups present in the particular anion AN1. From the viewpoint of a high effect of improving the sensitivity of the present composition, the iodo groups present in the particular anion AN1 are preferably bound directly to an aromatic ring included in the particular anion AN1. The iodo groups may be bound to a single aromatic ring or different aromatic rings in the particular anion AN1. The aromatic rings to which iodo groups are bound are preferably a benzene ring or a naphthalene ring, more preferably a benzene ring.

From the viewpoint of enhancing the effect of improving CDU performance, the particular anion AN1 preferably has a structure in which 4 or more iodine atoms are bound to a single aromatic ring, or a structure which has 2 or more aromatic rings each to which an iodine atom is bound and in which the total number of iodine atoms bound to the aromatic ring is 4 or greater. In the case where the particular anion AN1 has 2 or more aromatic ring to which an iodine atom is bound, the number of iodine atoms bound to each aromatic ring is 1 or greater, preferably 2 or greater, from the viewpoint of sensitivity. In the particular anion AN1, the description in relation to the number of iodo groups included in the particular anion AN1 is applied to the total number of the iodo groups bound to an aromatic ring. Thus, the total number of the iodo groups bound to an aromatic ring is preferably 5 or greater, more preferably 6 or greater. Also, from the viewpoint of achieving the balance between the effect of enhancing CDU performance and ease of synthesis, the total number of the iodo groups bound to an aromatic ring is preferably 10 or smaller, more preferably 9 or smaller.

Specific examples of the particular anion AN1 include the anions represented by the following formulas (b-1) to (b-19).

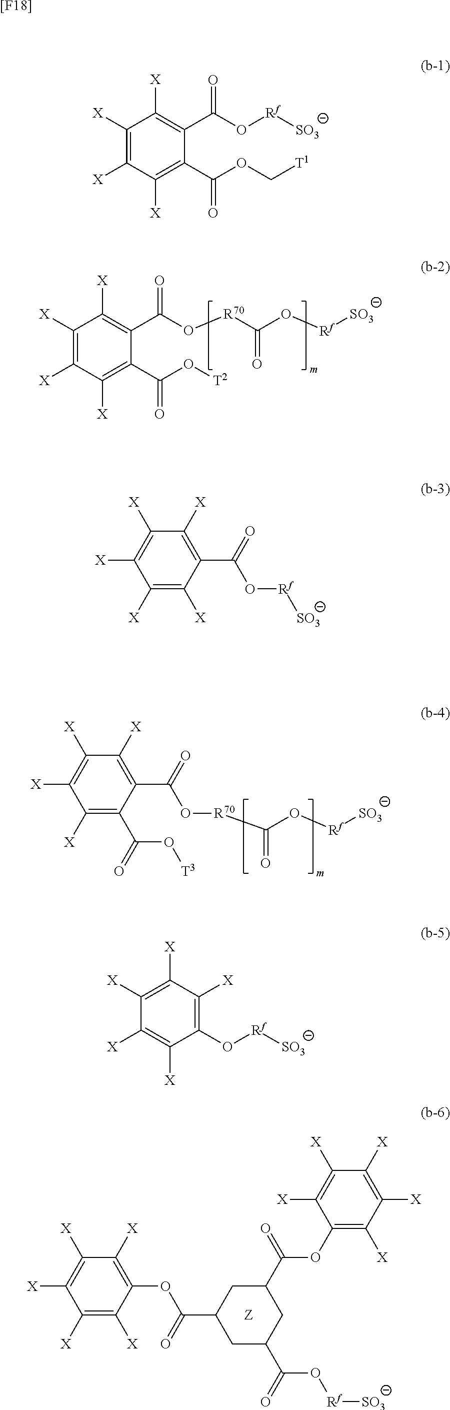

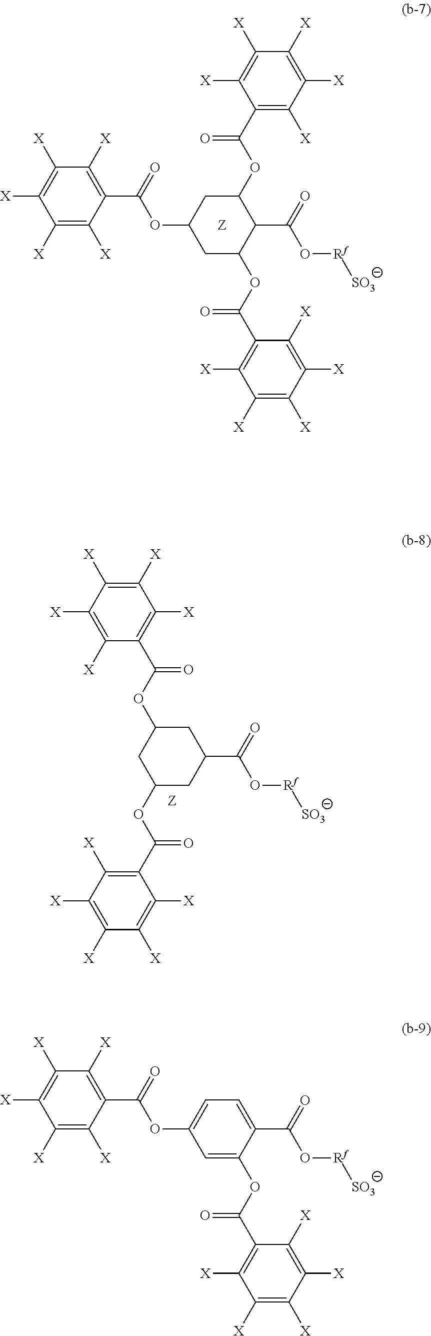

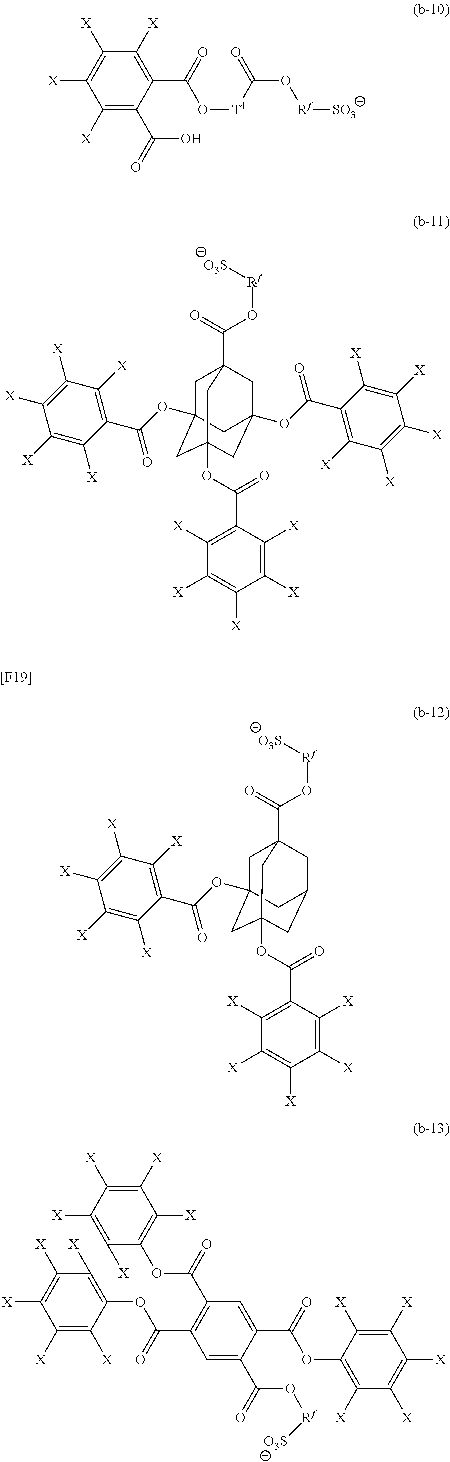

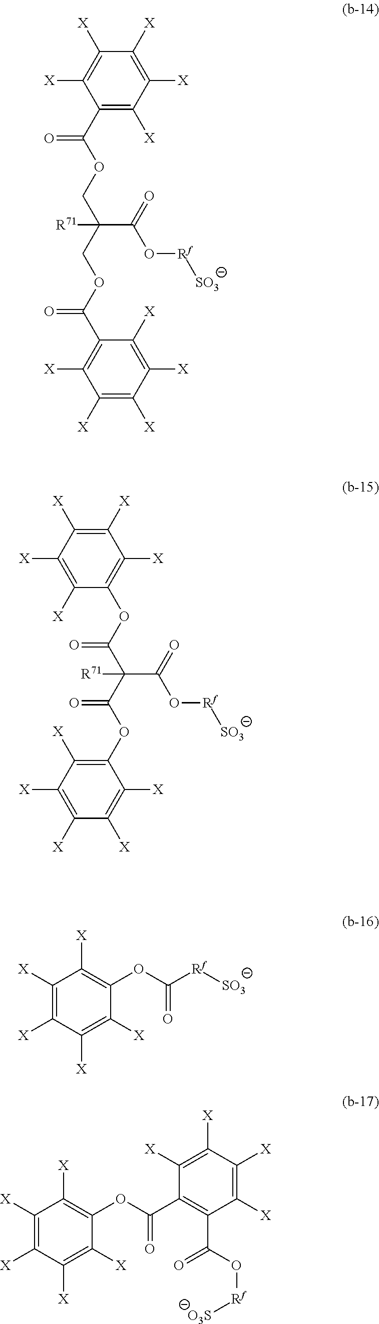

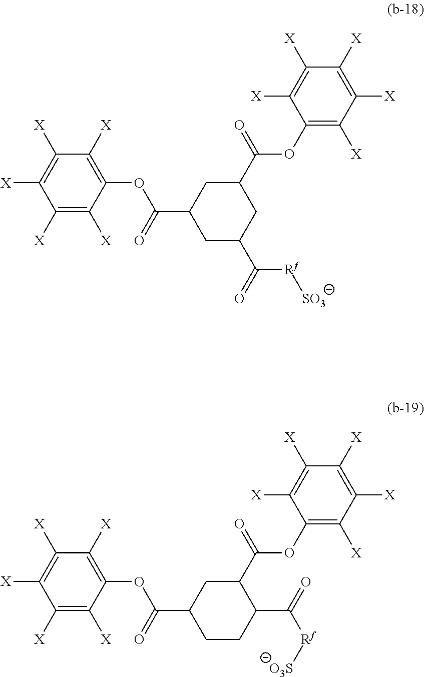

(In the formulas (b-1) to (b-19), X independently represents a hydrogen atom, a halogen atom, a hydroxy group, or a C1 to C3 alkyl group; 4 or more of a plurality of Xs in each formula are an iodine atom; R^{f} represents a C1 to C6 fluoroalkanediyl group; T¹ represents a hydrogen atom, a C1 to C3 alkyl group, an oxylanyl group, or an oxethanyl group; T² represents a hydrogen atom or a cycloalkyl group; T³ represents a hydrogen atom or an alkyl group; T⁴ represents a 1,2-ethanediyl group, a 1,2-ethenediyl group, a 1,2-ethynediyl group, a cycloalkanediyl group, a norbornanediyl group, an adamantanediyl group, or a phenylene group; R⁷⁰ represents a C1 to C6 alkanediyl group or fluoroalkanediyl group; R⁷¹ represents a hydrogen atom or an alkyl group; Z represents a benzene ring or a cyclohexane ring; and m is 0 or 1.)

The C1 to C6 fluoroalkanediyl group represented by any of R^{f} and R⁷⁰ may be linear-chain or branched. The C1 to C6 fluoroalkanediyl group represented by any of R^{f} and R⁷⁰ is preferably a C1 to C4 group. Specific examples thereof include —CF₂—, —CF₂—CF₂—, —CH(CF₃)—CF₂—, —CH₂—CF₂—, —CF₂—CH₂—, —C(CF₃)₂—CH₂—, and —CH₂—C(CF₃)₂—.

The C1 to C6 alkanediyl group represented by R⁷⁰ may be linear-chain or branched. The C1 to C6 alkanediyl group represented by R⁷⁰ is preferably a C1 to C3 group, more preferably a methylene group or an ethylene group.

The alkyl group represented by R⁷¹ may be linear-chain or branched. The alkyl group represented by R⁷¹ is preferably a C1 to C5 group, more preferably a methyl group or an ethyl

Specific examples of the particular anion AN1 include the organic anions represented by the following formulas. However, the examples of the particular anion AN1 are not limited to the following structures.

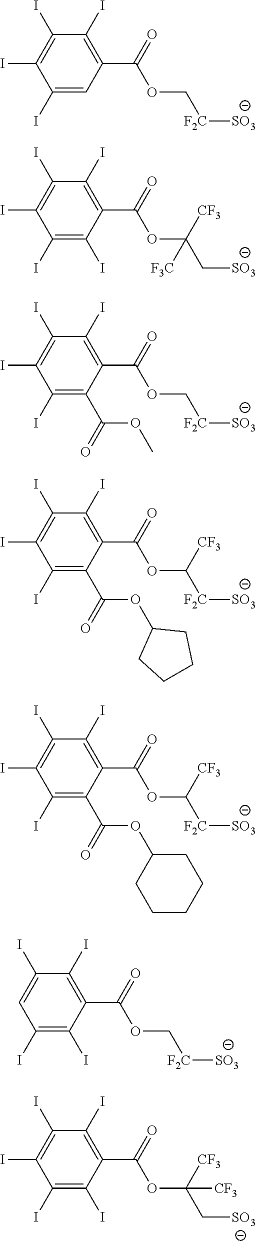

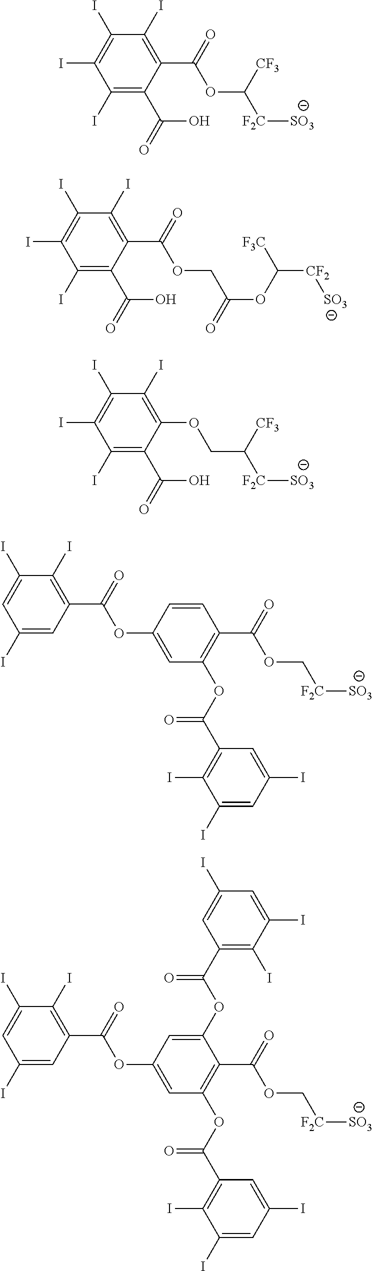

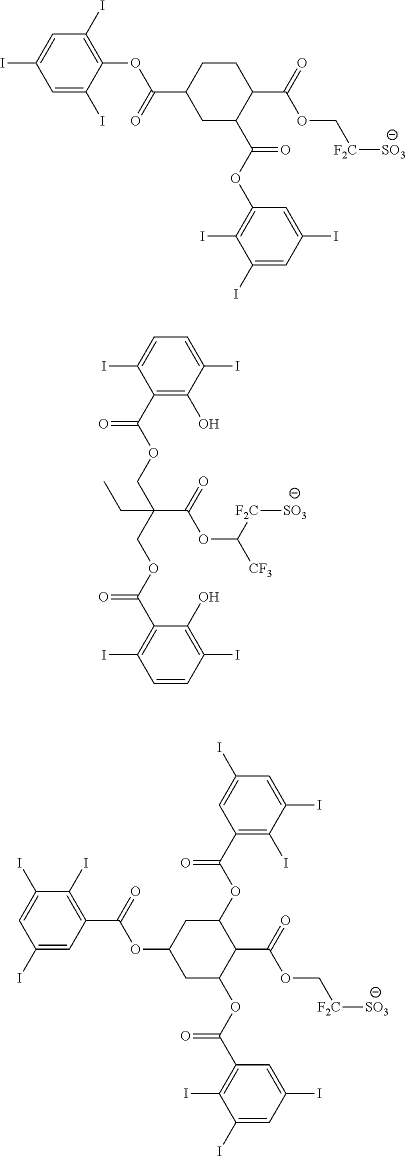

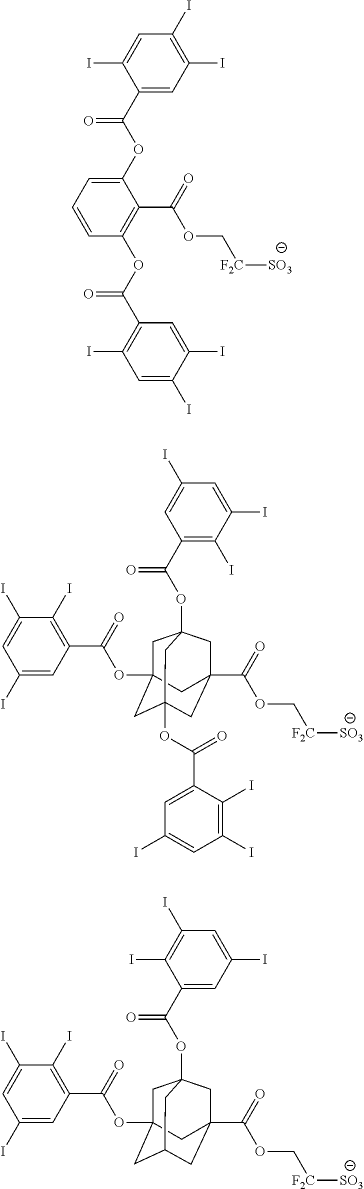

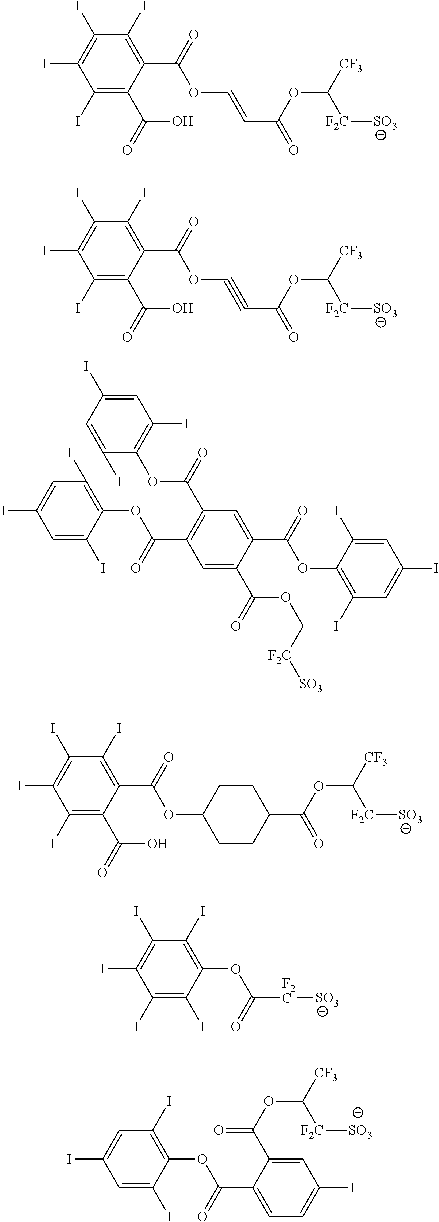

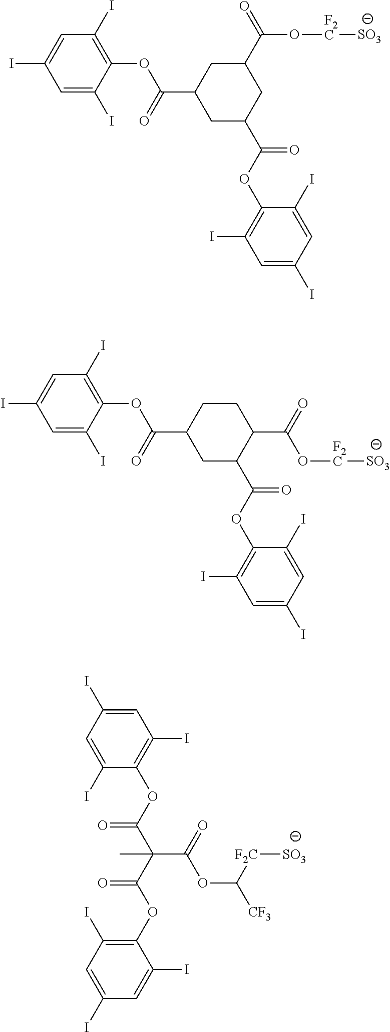

Specific examples of the acid-generating agent (B-1) include onium salts each formed of the particular cation and the particular anion AN1, as exemplified above. Further specific examples thereof include onium salts each formed of an onium cation represented by the aforementioned formula (1) and an organic anion represented by any of the aforementioned formulas (b-1) to (b-19); and onium salts each formed of an onium cation represented by the aforementioned formula (2) and an organic anion represented by any of the aforementioned formulas (b-1) to (b-19).

When the present composition contains the acid-generating agent (B-1) serving as the acid-generator (B), the relative amount of the acid-generating agent (B-1) in the present composition, with respect to 100 parts by mass of the polymer (A), is preferably 1 part by mass or more, more preferably 2 parts by mass or more, still more preferably 3 parts by mass or more. Also, the relative amount of the acid-generating agent (B-1) in the present composition, with respect to 100 parts by mass of the polymer (A), is preferably 20 parts by mass or less, more preferably 15 parts by mass or less, still more preferably 10 parts by mass or less. By adjusting the acid-generating agent (B-1) content to satisfy the aforementioned conditions, the sensitivity and CDU performance of the present composition can be further enhanced. The acid-generating agent (B-1) may be used singly or in combination of two or more species.

### Acid Diffusion Control Agent (B-2)

By incorporating the acid diffusion control agent (B-2) into the present composition, lithographic characteristics (in particular, CDU performance) of the present composition can be further enhanced. In addition, variation in line width of a resist pattern, which would otherwise be caused by variation in post exposure delay (from exposure to development) can be suppressed, to thereby yield a radiation-sensitive composition having excellent process stability.

The acid diffusion control agent (B-2) is a light-degradable base and a compound which generates, through exposure to the radiation, an acid weaker than the acid generated by radiation-sensitive acid-generating agent incorporated into the present composition. Specific examples of the acid diffusion control agent (B-2) include compounds that can generate carboxylic acid, sulfonic acid, or sulfonamide upon exposure to the radiation. The degree of acidity can be assessed on the basis of acid dissociation constant (pKa). The acid dissociation constant (pka) of the acid generated by the light-degradable base is generally −3 or higher, preferably −1 to 7, more preferably 0 to 5.

### (Onium Cation)

No particular limitation is imposed on the onium cation included in the acid diffusion control agent (B-2) (i.e., a particular cation), so long as it is a radiation-sensitive onium cation having one or more groups Rf¹s. Particularly, the particular cation preferably has a sulfonium cation structure or an iodonium cation structure. Specific examples of the particular cation having a sulfonium cation structure include the onium cations represented by the aforementioned formula (1), and specific examples of the particular cation having an iodonium cation structure include the onium cations represented by the aforementioned formula (2). Specific examples of the onium cations represented by the aforementioned formula (1) or (2) are mentioned above. The number of groups Rf¹s included in the particular cation is preferably 2 or greater, from the viewpoint of achieving high sensitivity while favorable CDU performance of the present composition is maintained. To the bonding position of group Rf¹, the same description as mentioned in relation the particular cation included in the acid-generating agent (B-1) may be applied.

### (Organic Anion)

The organic anion included in the acid diffusion control agent (B-2) (hereinafter may also be referred to as a “particular anion AN2”) is, for example, a sulfonate anion structure, an imide anion structure, a methyl anion structure, a carboxylate anion structure, etc. Among them, the particular anion AN2 preferably has a sulfonate anion structure or a carboxylate anion structure, more preferably a carboxylate anion structure.

By incorporating an acid diffusion control agent formed of the particular cation and the particular anion AN2 into the present composition, CDU performance can be enhanced while the sensitivity of the present composition is maintained. The number of iodo groups included in the particular anion AN2 is essentially 4 or greater. From the viewpoint of establish the balance between the effect of enhancing CDU performance and ease of synthesis, the number of iodo groups included in the particular anion AN2 is preferably 10 or smaller, more preferably 9 or smaller.

No particular limitation is imposed on the bonding positions of the iodo groups in the particular anion AN2. From the viewpoint of achieving a high effect of enhancing the sensitivity of the present composition, preferably, one or more iodo groups among the iodo groups included in the particular anion AN2 are directly bound to an aromatic ring present in the particular anion AN2. More preferably, all the iodo groups are directly bound to an aromatic ring present in the particular anion AN2. The iodo groups may be bound to a single aromatic ring or to different aromatic rings in the particular anion AN2. Specific examples including preferred aromatic rings to which iodo groups are bound, and specific examples including preferred bonding position of iodo atoms, the same descriptions as mentioned in relation to the particular anion AN1 included in the acid-generating agent (B-1) are applied.

Specific examples of the particular anion AN2 include the anions represented by the following formulas (b-20) to (b-24).

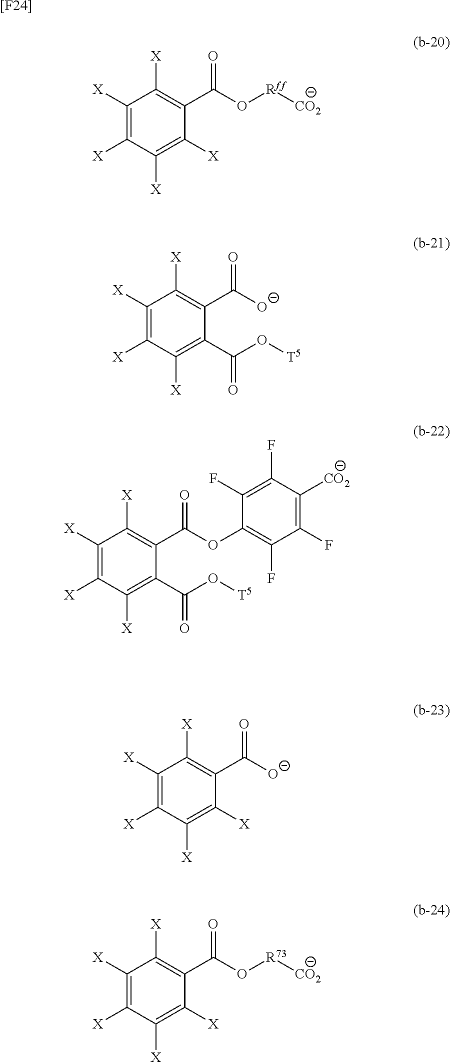

(In the formulas (b-20) to (b-24), each of Xs independently represents a hydrogen atom, a halogen atom, a hydroxy group, or a C1 to C3 alkyl group; 4 or more Xs in a plurality of Xs present in each formula are iodine atoms; R^{ff} represents a C1 to C6 alkanediyl group or a C1 to C6 fluoroalkanediyl group; R⁷³ represents a fluorinated divalent cyclic group; and T⁵ represents an alkyl group or a cycloalkyl group.)

In the aforementioned formulas (b-20) to (b-24), examples of the C1 to C6 fluoroalkanediyl group represented by R^{ff} include the same groups as exemplified in relation to R^{f} in the aforementioned formulas (b-1) to (b-19). Examples of the C1 to C6 alkanediyl group represented by R^{ff} include the same groups as exemplified in relation to R⁷⁰ in the aforementioned formulas (b-1) to (b-19).

Examples of the fluorinated divalent cyclic group represented by R⁷³ include groups each formed by substituting one or more hydrogen atoms of a C3 to C20 monovalent alicyclic hydrocarbon group or a C6 to C20 monovalent aromatic hydrocarbon group with a fluorine atom. Specific examples of the alicyclic hydrocarbon group and the aromatic hydrocarbon group include the same groups as exemplified in relation to the C1 to C20 monovalent hydrocarbon group represented by any of R¹³ to R¹⁵, and R¹⁷ to R¹⁹.

Specific examples of the particular anion AN2 include the organic anions represented by the following formulas. However, the examples of the particular anion AN2 are not limited to the following structures.

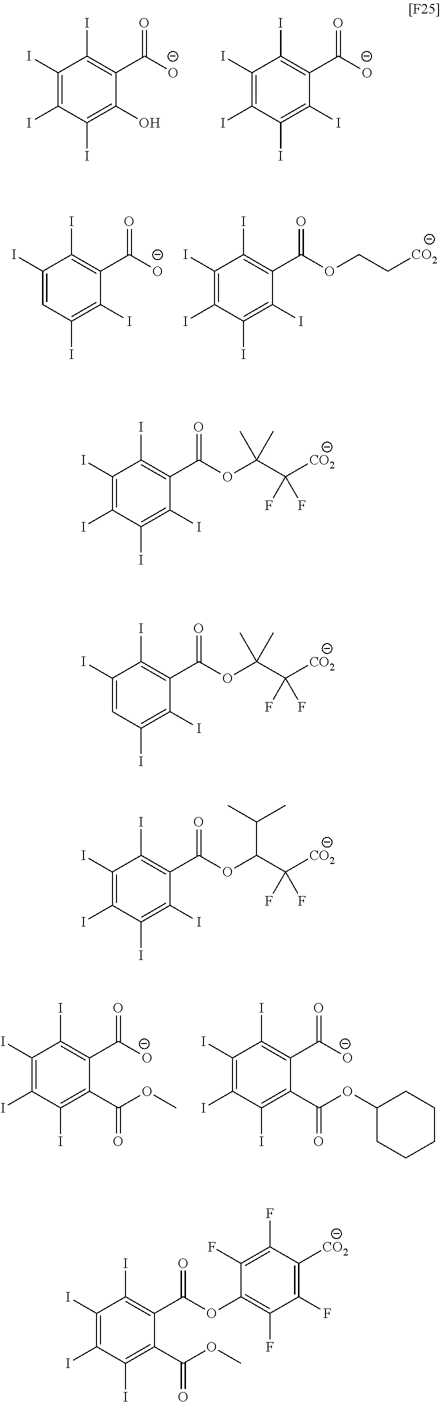

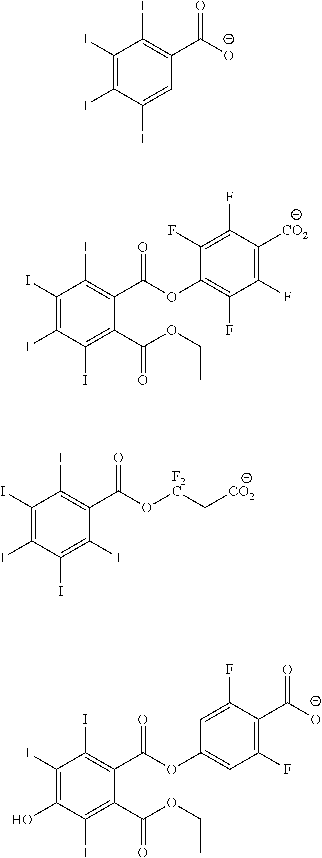

Specific examples of the acid diffusion control agent (B-2) include onium salts each formed of the particular cation and the particular anion AN2, as exemplified above. Further specific examples thereof include onium salts each formed of an onium cation represented by the aforementioned formula (1) and an organic anion represented by any of the aforementioned formulas (b-20) to (b-24); and onium salts each formed of an onium cation represented by the aforementioned formula (2) and an organic anion represented by any of the aforementioned formulas (b-20) to (b-24).

When the present composition contains the acid diffusion control agent (B-2) serving as the acid-generator (B), the relative amount of the acid diffusion control agent (B-2) in the present composition, with respect to 100 parts by mass of the polymer (A), is preferably 0.1 parts by mass or more, more preferably 1 part by mass or more, still more preferably 2.5 parts by mass or more. Also, the relative amount of the acid diffusion control agent (B-2) in the present composition, with respect to 100 parts by mass of the polymer (A), is preferably 20 parts by mass or less, more preferably 15 parts by mass or less, still more preferably 10 parts by mass or less. By adjusting the acid diffusion control agent (B-2) content to satisfy the aforementioned conditions, the sensitivity and CDU performance of the present composition can be further enhanced. The acid diffusion control agent (B-2) may be used singly or in combination of two or more species.

### <(C) Additional Acid-Generator>

When the acid-generator (B) in the present composition is the acid-generating agent (B-1), preferably, the present composition further contains an additional acid diffusion control agent (i.e., an acid diffusion control agent (C-2)). Also, when the acid-generator (B) in the present composition is the acid diffusion control agent (B-2), preferably, the present composition further contains an additional acid-generating agent (i.e., an acid-generating agent (C-1)).

### Acid-Generating Agent (C-1)

As the acid-generating agent (C-1), an onium salt compound formed of a radiation-sensitive onium cation and an organic anion is preferably used. However, when the onium cation forming the acid-generating agent (C-1) has groups Rf¹s, the number of iodine atoms present in the organic anion forming the acid-generating agent (C-1) is 3 or smaller. When the organic anion forming the acid-generating agent (C-1) has 4 or more iodine atoms, the onium cation forming the acid-generating agent (C-1) has no group Rf¹. Alternatively, the acid-generating agent (C-1) may also be an onium salt compound formed of an onium cation having no group Rf¹ and an organic anion having 3 or less iodine atoms. The acid-generating agent (C-1) may be used singly or in combination of two or more species.

As the onium cation included in the acid-generating agent (C-1), a cation having a sulfonium cation structure or an iodonium cation structure is preferably employed, from the viewpoint of enhancing lithographic characteristics of the present composition. When the cation has a sulfonium cation structure, specific examples of the cation include a cation represented by the aforementioned formula (1) and a cation represented by the aforementioned formula (1) and satisfying condition: a1+a2+a3=0. When the cation has an iodonium cation structure, specific examples of the cation include a cation represented by the aforementioned formula (2) and a cation represented by the aforementioned formula (2) and satisfying condition: a7+a8=0.

No particular limitation is imposed on the organic anion present in the acid-generating agent (C-1). Specific examples of the organic anion include organic anions having a sulfonate anion structure, an imide anion structure, and a methide anion structure. Among them, the organic anion is preferably an organic anion having a sulfonate anion structure. Specific examples of the organic anion present in the acid-generating agent (C-1) include organic anions represented by the following formula (7).

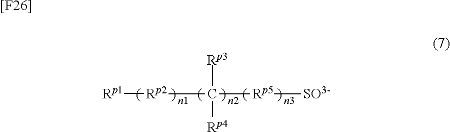

(In the formula (7), n1 is an integer of 0 to 10; n2 is an integer of 0 to 10; n3 is an integer of 1 to 10; n1+n2+n3 is 1 to 30; when n1 is ≥2, a plurality of R^{p2}s are identical to or different from one another; when n2 is ≥2, a plurality of R^{p3}s are identical to or different from one another, and a plurality of Reds are identical to or different from one another; when n3 is ≥2, a plurality of R^{p5}s are identical to or different from one another; R^{p1} represents a monovalent group having a ≥5-membered ring structure; R^{p2} represents a divalent connecting group; each of R^{p3} and R^{p4} independently represents a hydrogen atom, a fluoro group, a C1 to C20 monovalent hydrocarbon group, or a C1 to C20 monovalent fluorinated hydrocarbon group; RPS represents —CR^{p6}R^{p7}— or a fluorophenylene group; each of R^{p6} and R^{p7} independently represents a hydrogen atom, a fluoro group, or a C1 to C20 monovalent fluorinated hydrocarbon group; when n3 is 1, the case where each of R^{p6} and R^{p7} is a hydrogen atom is excluded; and when n3 is ≥2, the case where all of the plurality of R^{p6} and R^{p7} are hydrogen atoms is excluded.)

In the aforementioned formula (7), examples of the monovalent group having a ≥5-membered ring structure and represented by R^{p1} include a monovalent group having a ≥5-membered alicyclic structure, a monovalent group having a ≥5-membered aliphatic heterocyclic structure, a monovalent group having a ≥6-membered aromatic hydrocarbon cyclic structure, and a monovalent group having a ≥5-membered aromatic heterocyclic structure.

Examples of the ≥5-membered alicyclic structure include monocyclic cycloalkane structures such as a cyclopentane structure, a cyclohexane structure, a cycloheptane structure, a cyclooctane structure, a cyclononane structure, a cyclodecane structure, and a cyclododecane structure; monocyclic cycloalkene structures such as a cyclopentene structure, a cyclohexene structure, a cycloheptene structure, a cyclooctene structure, and a cyclodecene structure; polycyclic cycloalkane structures such as a norbornane structure, an adamantane structure, a tricyclodecane structure, and a tetracyclododecane structure; and polycyclic cycloalkene structures such as a norbornene structure and a tricyclodecene structure.

Examples of the ≥5-membered aliphatic heterocyclic structure include lactone structures such as a hexanolactone structure and a norbornanelactone structure; sultone structures such as a hexanosultone structure and a norbornanesultone structure; oxygen atom-containing heterocyclic structures such as an oxacycloheptane structure, an oxanorbornane structure, and a cyclic acetal structure; nitrogen atom-containing heterocyclic structures such as an azacyclohexane structure and a diazabicyclooctane structure; and sulfur atom-containing heterocyclic structures such as a thiacyclohexane structure and a thianorbornane structure.

Examples of the ≥6-membered aromatic hydrocarbon cyclic structure include a benzene structure, a naphthalene Structure, a phenanthrene structure, and an anthracene structure. Examples of the ≥5-membered aromatic heterocyclic structure include oxygen atom-containing heterocyclic structures such as a furan structure, a pyran structure, and a benzopyran structure; and nitrogen atom-containing heterocyclic structures such as a pyridine structure, a pyrimidine structure, and an indole structure.

Meanwhile, a part or the entirety of the hydrogen atoms present in a cyclic structure of R^{p1} may be substituted by a substituent. Examples of the substituent include a halogen group, a hydroxy group, a carboxy group, a cyano group, a nitro group, an alkoxy group, an alkoxycarbonyl group, an alkoxycarbonyloxy group, an acyl group, and an acyloxy group.

Among the aforementioned relevant groups, the monovalent group represented by R^{p1} is preferably a group having a ≥6-membered aromatic hydrocarbon cyclic structure or a group having a ≥5-membered aromatic heterocyclic structure, particularly preferably a group having a benzene structure.

Examples of the divalent bonding group represented by R^{p2} include a carbonyl group, an ether group, a carbonyloxy group, a sulfide group, a thiocarbonyl group, a sulfonyl group, and a divalent hydrocarbon group. Of these, a carbonyloxy group, a sulfonyl group, an alkanediyl group, and a cycloalkanediyl group are preferred, with a carbonyloxy group and a cycloalkanediyl group being more preferred, a carbonyloxy group and a norbornanediyl group being still more preferred, a carbonyloxy group being yet more preferred.

Examples of the C1 to C20 monovalent hydrocarbon group represented by any of R^{p3} and R^{p4} include a C1 to C20 alkyl group. Examples of the C1 to C20 monovalent fluorinated hydrocarbon group represented by any of R^{p3} and R^{p4} include a C1 to C20 fluorinated alkyl group. Each of R^{p3} and R^{p4} is preferably a hydrogen atom, a C1 to C3 alkyl group, a fluoro group, or a C1 to C3 fluoroalkyl group.

Examples of the C1 to C20 monovalent fluorinated hydrocarbon group represented by any of R^{p6} and R^{p7} include a C1 to C20 fluoroalkyl group. Each of R^{p6} and R^{p1} is preferably a fluoro group or a fluoroalkyl group, with a fluoro group or a perfluoroalkyl group being more preferred, a fluoro group or a trifluoromethyl group being still more preferred, a fluoro group being particularly preferred. When n3 is 1, preferably, both R^{p6} and R^{p7} are a fluoro group, or R^{p6} is a fluoro group and R^{p7} is a hydrogen atom or a trifluoromethyl group.

The parameter n1 is preferably 0 to 5, more preferably 0 to 3, still more preferably 0 to 2, particularly preferably 0 or 1. The parameter n2 is preferably 0 to 5, more preferably 0 to 2, still more preferably 0 or 1, particularly preferably 0. The parameter n3 is preferably 1 to 5, more preferably 1 to 3, still more preferably 1 or 2. By adjusting n3 to satisfy the aforementioned conditions, the strength of the acid generated from the acid-generating agent (C-1) can be enhanced, to thereby further enhance the lithographic characteristics and sensitivity of the present composition. The sum n1+n2+n3 is preferably 2 or greater, and also, preferably 10 or smaller, more preferably 5 or smaller.

Specific examples of the organic anion included in the acid-generating agent (C-1) include the organic anions represented by the following formula. Also, when the onium cation forming the acid-generating agent (C-1) has no substituted group Rf¹, the organic anion forming the acid-generating agent (C-1) may be a particular anion AN1. Specific examples of the particular anion AN1 include the same groups as exemplified in relation to the particular anion AN1 forming the acid-generating agent (B-1). However, the organic anion forming the acid-generating agent (C-1) is not limited to these structures.

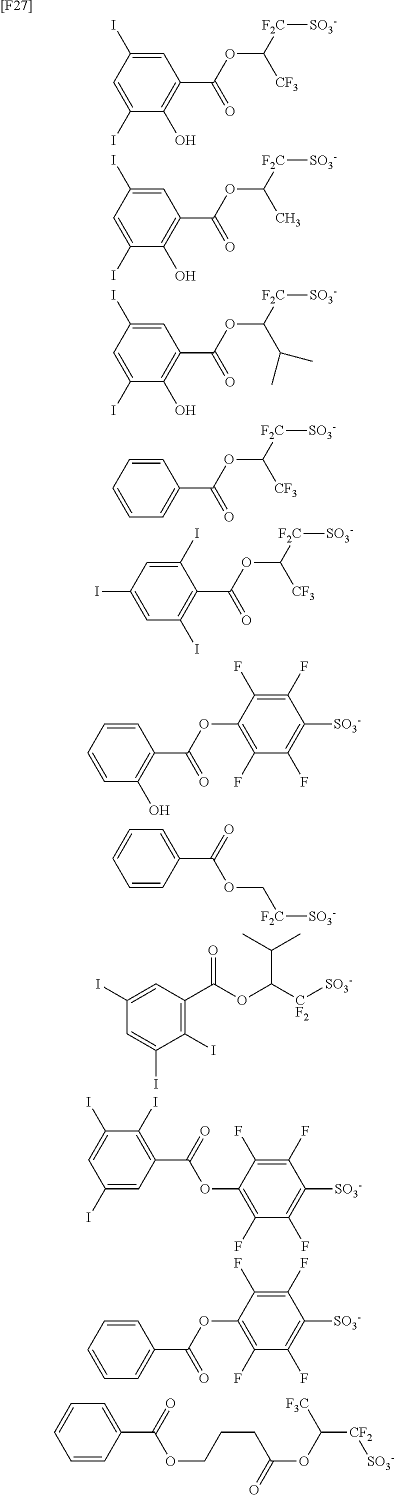

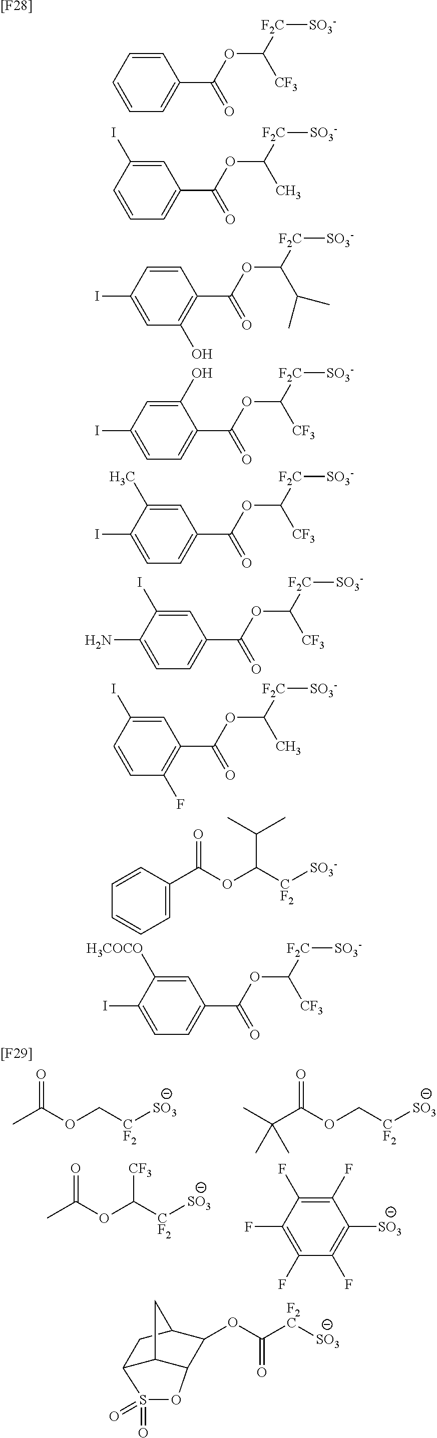

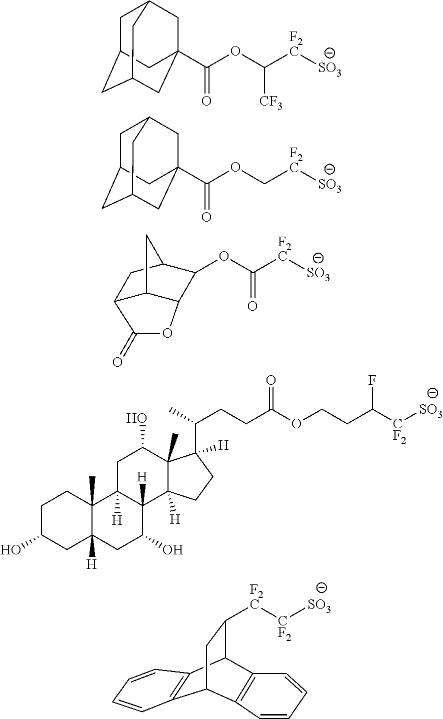

The relative amount of the radiation-sensitive acid-generating agent in the present composition (i.e., the total amount of the acid-generating agent (B-1) and the acid-generating agent (C-1)), with respect to 100 parts by mass of the polymer (A), is preferably 1 part by mass or more, more preferably 2.5 parts by mass or more, still more preferably 3.5 parts by mass or more. Also, the radiation-sensitive acid-generating agent content, with respect to 100 parts by mass of the polymer (A), is preferably 20 parts by mass or less, more preferably 15 parts by mass or less, still more preferably 10 parts by mass or less. By adjusting the radiation-sensitive acid-generating agent content to satisfy the aforementioned conditions, the sensitivity and CDU performance of the present composition can be further enhanced.

### Acid Diffusion Control Agent (C-2)

The acid diffusion control agent (C-2) is, for example, a nitrogen-containing compound or a light-degradable base. Examples of the nitrogen-containing compound include an amino group-containing compound (e.g., alkylamine, aromatic amine, or polyamine), an amide group-containing compound, a urea compound, a nitrogen-containing heterocyclic compound, and a nitrogen-containing compound having an acid-releasable group.

The light-degradable base serving as the additional acid diffusion control agent (hereinafter may also be referred to as a “light-degradable base (C-2)” is preferably such a compound that the acid generated through exposure to the radiation cannot substantially release an acid-releasable group in the present composition, when the composition is heated at 110° C. for 1 minute.

As the light-degradable base (C-2), an onium salt compound formed of a radiation-sensitive onium cation and an organic anion is preferably employed. When the onium cation forming the light-degradable base (C-2) has group Rf¹, the number of iodine atoms of the organic anion forming the light-degradable base (C-2) is 3 or smaller. When the organic anion forming the light-degradable base (C-2) has 4 or more iodine atoms, the onium cation forming the light-degradable base (C-2) has no group Rf¹. Alternatively, the light-degradable base (C-2) may be an onium salt compound formed of an onium cation having no group Rf¹ and an organic anion having 3 or less iodine atoms. The light-degradable base (C-2) may be used singly or in combination or two or more species.

From the viewpoint of achieving suitable lithographic characteristics of the present composition, an onium salt which generates a carboxylic acid, a sufonic acid, or a sulfonamide through exposure to the radiation is preferably used as the light-degradable base (C-2). The acid dissociation constant (pka) of the acid generated by the light-degradable base is generally −3 or more, preferably −1 to 7, more preferably 0 to 5.

Specific examples of the light-degradable base (C-2) include the onium salt compounds represented by the following formula (9).

[F30]

E⁻Z⁺(9)

(In the formula (9), E-represents an organic anion represented by “R⁵¹—COO—,” “R⁵²—SO₂—N⁻—R⁵¹,” or “R⁵¹—SO₃—”; each of R⁵¹ and R⁵² independently represents a C1 to C30 monovalent organic group; when E⁻ is an organic anion represented by “R⁵¹—SO;”, “no fluorine atom is bound to a carbon atom to which “SO₃—” is bound; and Z⁺ represents a radiation-sensitive onium cation, with the case where E⁻ has 4 or more iodine atoms, and Z⁺ has a fluorine atom being excluded.)

In the aforementioned formula (9), examples of the C1 to C30 monovalent organic group represented by R⁵¹ include a C1 to C30 monovalent hydrocarbon group; a C1 to C30 monovalent group γ having a divalent heteroatom-containing group between a carbon-carbon bond or at an end on the chemical bond side in a hydrocarbon group; and a monovalent group formed by substituting at least one hydrogen atom of the hydrocarbon group or the monovalent group γ with a monovalent heteroatom-containing group. Among them, the C1 to C30 monovalent organic group represented by R⁵¹ is preferably a monovalent group having a substituted or unsubstituted aromatic ring.

Examples of the C1 to C30 monovalent organic group represented by R⁵² include a substituted or unsubstituted alkyl group and a substituted or unsubstituted cycloalkyl group. Examples of the substituent in the substituted alkyl group include a fluoro group. Examples of the substituent in the substituted cycloalkyl group include a C1 to C10 alkyl group, a fluoro group, and an iodo group.

The radiation-sensitive onium cation represented by Z⁺ preferably has a sulfonium cation structure or an iodonium cation structure, more preferably a triarylsulfonium cation structure or a diaryliodonium cation structure.

When the organic anion forming the light-degradable base (C-2) has 3 or less iodine atoms, the onium cation forming the light-degradable base (C-2) may be a particular cation (i.e., an onium cation having substituted group Rf¹). Specific examples of the particular cation include the same groups as exemplified in relation to the particular cation forming the acid diffusion control agent (B-2).

The organic anion included in the light-degradable base (C-2) preferably has a carboxylate anion structure or a sulfonate anion structure. Specific examples of the organic anion include the organic anions represented by the following formulas. When the onium cation forming the acid diffusion control agent (C-2) has no group Rf¹, the organic anion forming the acid diffusion control agent (C-2) may be the particular anion AN2. Specific examples of the particular anion AN2 include the same groups as exemplified in relation to the particular anion AN2 forming the acid diffusion control agent (B-2). However, the organic anion included in the light-degradable base (C-2) is not limited to these structures.

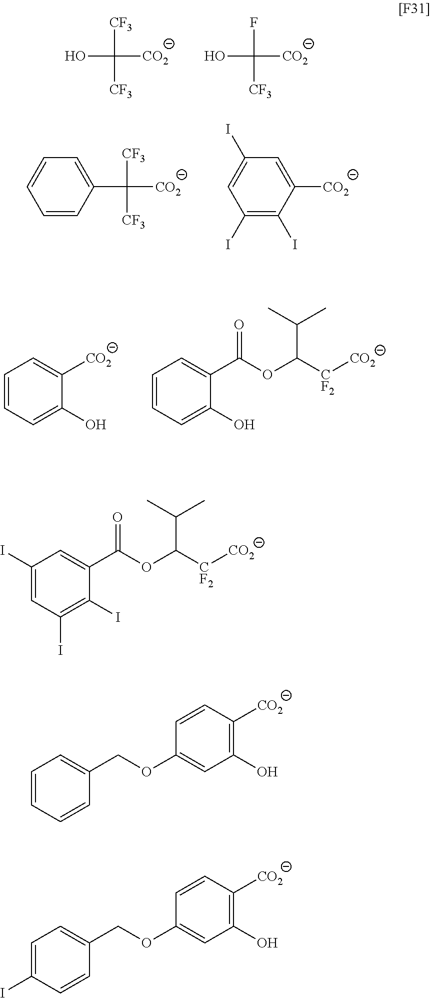

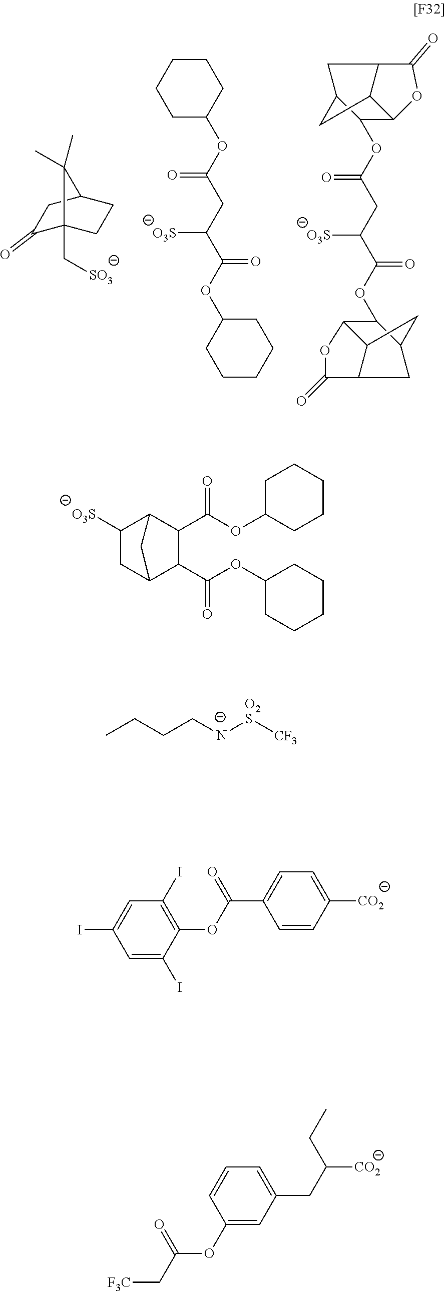

When the present composition contains both the acid-generating agent (B-1) and the acid diffusion control agent (C-2), the relative amount of the additional acid diffusion control agent in the present composition, with respect to 100 parts by mass of the polymer (A), is preferably 0.1 parts by mass or more, more preferably 1 part by mass or more, still 10 more preferably 2.5 parts by mass or more. Also, the relative amount of the acid diffusion control agent (C-2) in the present composition, with respect to 100 parts by mass of the polymer (A), is preferably 20 parts by mass or less, more preferably 15 parts by mass or less, still more preferably 10 parts by mass or less. By adjusting the acid diffusion control agent (C-2) content to satisfy the aforementioned conditions, the CDU performance of the present composition can be further enhanced. The additional acid diffusion control agent may be used singly or in combination of two or more species.

Also, when the present composition contains the acid diffusion control agent, the relative amount of the acid diffusion control agent in the present composition (i.e., the total relative amount of the acid diffusion control agent (B-2) and the acid diffusion control agent (C-2)), with respect to 100 parts by mass of the polymer (A), is preferably 0.1 parts by mass or more, more preferably 1.5 parts by mass or more, still more preferably 2.5 parts by mass or more. Also, the acid diffusion control agent content, with respect to 100 parts by mass of the polymer (A), is preferably 20 parts by mass or less, more preferably 15 parts by mass or less, still more preferably 10 parts by mass or less.

### <(D) Solvent>

No particular limitation is imposed on the solvent (D), so long as the solvent can dissolve or disperse the polymer (A), the acid-generator (B), and an optional component incorporated into the present composition therein. Examples of the solvent (D) include an alcohol, an ether, a ketone, an amide, an ester, and a hydrocarbon.

Examples of the alcohol include C1 to C18 aliphatic monoalcohols such as 4-methyl-2-pentanol and n-hexanol; C3 to C18 alicyclic monoalcohols such as cyclohexanol; C2 to C18 polyhydric alcohols such as 1,2-propylene glycol; and C3 to C19 polyhydric alcohol partial ethers such as propylene glycol monomethyl ether. Examples of the ether include dialkyl ethers such as diethyl ether, dipropyl ether, dibutyl ether, dipentyl ether, diisoamyl ether, dihexyl ether, and diheptyl ether; cyclic ethers such as tetrahydrofuran and tetrahydropyran; and aromatic ring-containing ethers such as diphenyl ether and anisole.

Examples of the ketone include chain ketones such as acetone, methyl ethyl ketone, methyl n-propyl ketone, methyl n-butyl ketone, diethyl ketone, methyl isobutyl ketone, 2-heptanone, ethyl n-butyl ketone, methyl n-hexyl ketone, diisobutyl ketone, and trimethylnonanone; cyclic ketones such as cyclopentanone, cyclohexanone, cycloheptanone, cyclooctanone, and methylcyclohexanone; and 2,4-pentanedione, acetonylacetone, acetophenone, and diacetone alcohol. Examples of the amide include cyclic amides such as N,N′-dimethylimidazolidinone and N-methylpyrrolidone; and chain amides such as N-methylformamide, N, N-dimethylformamide, N, N-diethylformamide, acetamide, N-methylacetamide, N, N-dimethylacetamide, and N-methylpropionamide.

Examples of the ester include monocarboxylic acid ester-type solvents such as n-butyl acetate and ethyl lactate; polyhydric alcohol carboxylates such as propylene glycol acetate; polyhydric alcohol partial ester carboxylates such as propylene glycol monomethyl ether acetate; polybasic carboxylic acid diesters such as diethyl oxalate; carbonates such as dimethyl carbonate and diethyl carbonate; and cyclic esters such as γ-butyrolactone. Examples of the hydrocarbon include C5 to C12 aliphatic hydrocarbons such as n-pentane and n-hexane; and C6 to C16 aromatic hydrocarbons such as toluene and xylene.

Among the above solvents, the solvent (D) preferably includes at least one member selected from the group consisting of the ester and the ketone, more preferably at least one member selected from the group consisting of polyhydric alcohol partial ether carboxylates and cyclic ketones, still more preferably one or more species of propylene glycol monomethyl ether acetate, ethyl lactate, and cyclohexanone. The solvent (D) may be used singly or in combination of two or more species.

### <(E) High-Fluorine Content Polymer>

The high-fluorine content polymer (E) (hereinafter may also be referred to simply as a “polymer (E)”) is a polymer having a fluorine atom content (by mass) greater than that of the polymer (A). The polymer (E) is incorporated into the present composition as, for example, a water-repellent additive.

No particular limitation is imposed on the fluorine atom content of the polymer (E), so long as it is greater than the fluorine atom content of the polymer (A). From the viewpoint of achieving a satisfactory effect of enhancing the water repellency on the basis of localization of the polymer (E) to an upper layer of the resist film, the fluorine atom content of the polymer (E) is preferably 1 mass % or more, more preferably 2 mass % or more, still more preferably 4 mass % or more, yet more preferably 7 mass % or more. Also, the fluorine atom content of the polymer (E) is preferably 60 mass % or less, more preferably 40 mass % or less, still more preferably 30 mass % or less. The fluorine atom content (mass %) of a polymer can be obtained by determining the structure of the polymer through 13C-NMR spectrometry or the like and calculating the content based on the structure determined.

The Mw of the polymer (E), as determined through GPC, is preferably 1,000 or higher, more preferably 3,000 or higher, still more preferably 4,000 or higher. Also, the Mw of the polymer (E) is preferably 50,000 or lower, more preferably 30,000 or lower, still more preferably 20,000 or lower. The molecular weight distribution (Mw/Mn), which is the ratio of Mw to Mn of the polymer (E) determined through GPC, is generally 1 or greater, preferably 1.2 or greater. Also, the Mw/Mn is preferably 5 or smaller, more preferably 3 or smaller.

When the present composition contains the polymer (E), the relative amount of the polymer (E) in the present composition, with respect to 100 parts by mass of the polymer (A), is preferably 0.1 parts by mass or more, more preferably 1 part by mass or more, still more preferably 2 parts by mass or more. Also, the polymer (E) content, with respect to 100 parts by mass of the polymer (A), is preferably 20 parts by mass or less, more preferably 10 parts by mass or less, still more preferably 7 parts by mass or less. The polymer (E) may be used singly or in combination of two or more species.

### <Additional and Optional Component>

The present composition may further contain a component which differs from the aforementioned polymer (A), acid-generator (B), solvent (D), and high-fluorine content polymer (E) (hereinafter the component may also be referred to as “additional and optional component”). Examples of the additional and optional component include a surfactant, a compound having an alicyclic skeleton (e.g., 1-adamantanecarboxylic acid, 2-adamantanone, or t-butyl deoxycholate), a sensitizer, and a localization accelerator. So long as the effect of the present disclosure are not impaired, the additional and optional component content of the present composition may be appropriately set depending on the property of the component.

### <Method of Producing Radiation-Sensitive Composition>

The present composition may be produced through, for example, the following procedure: mixing the polymer (A) and the acid-generator (B) with optional components such as the solvent (D) and high-fluorine content polymer (E) at a desired ratio and filtering the resultant mixture preferably by means of a filter (e.g., a filter having a pore size of about 0.2 μm) or the like.

The solid content of the present composition is preferably 0.1 mass % or more, more preferably 0.5 mass % or more, still more preferably 1 mass % or more. Also, the solid content of the present composition is preferably 50 mass % or less, more preferably 20 mass % or less, still more preferably 5 mass % or less. Adjusting the solid content of the present composition to satisfy the above conditions is preferred, since coatability of the composition can be enhanced, to thereby obtain a resist pattern having a suitable shape.

The thus-obtained present composition may also be used as a composition for forming a positive pattern, which is employed for pattern formation by use of an alkaline developer. Alternatively, the present composition may be used as a composition for forming a negative pattern by use of a developer containing organic solvent.

### <Method of Forming Resist Pattern>

The resist pattern formation method of the present disclosure includes a step of applying the present composition on one surface of a substrate (hereinafter may also be referred to as a “application step”), a step of exposing a resist film obtained in the application step (hereinafter may also be referred to as a “exposure step”), and a step of developing the exposed resist film (hereinafter may also be referred to as a “development step”). Examples of the pattern obtained through the resist pattern formation method of the present disclosure include a line-and-space pattern and a hole pattern. Since a resist film is formed by use of the present composition in the resist pattern formation method of the present disclosure, a resist pattern which exhibits excellent sensitivity and small CDU can be formed. The steps will next be described in detail.

### [Application Step]

In the application step, the present composition is applied onto one surface of a substrate, to thereby form a resist film on the substrate. A conventionally known substrate can be used as a substrate on which resist film is to be formed. Examples of the substrate include a silicon wafer and a wafer coated with silicon dioxide or aluminum. Alternatively, an organic or inorganic anti-reflection film (see, for example, Japanese Patent Publication (kokoku) No. 1994-12452 or Japanese Patent Application laid-Open (kokai) No. 1984-93448) may be formed on a substrate to be used. Examples of the method of applying the present composition include spin coating, flow casting, and roller coating. After application, the applied composition may be subjected to pre-baking (PB) so as to evaporate the solvent remaining in the coating film. The temperature of PB is preferably 60 to 140° C., more preferably 80 to 130° C. The time of PB is preferably 5 to 600 seconds, more preferably 10 to 300 seconds. The average thickness of the formed resist film is preferably 10 to 1,000 nm, more preferably 20 to 500 nm.

### [Exposure Step]

In the exposure step, the resist film formed through the above application step is exposed. In the exposure, the resist film is irradiated with a radiation by the mediation of a photomask or, in some cases, a liquid immersion medium such as water. The radiation is selected in accordance with the line width of a target pattern, and examples thereof include electromagnetic waves such as visible light, a UV ray, a far-UV ray, an extreme UV (EUV) ray, an X-ray, and a γ-ray; and charged particle rays such as an electron beam and an x-ray. Among them, the radiation applied to the resist film formed from the present composition is preferably a far-UV ray, an EUV ray, or an electron beam, more preferably ArF excimer laser light (wavelength: 193 nm), KrF excimer laser light (wavelength: 248 nm), an EUV ray, or an electron beam, still more preferably ArF excimer laser light, an EUV ray, or an electron beam, yet more preferably an EUV ray or an electron beam, particularly preferably an EUV ray. The present composition is suited for forming a resist pattern through exposure to an EUV ray.

After completion of the above radiation exposure, post exposure baking (PEB) is preferably performed. Through PEB, the difference in dissolution performance with respect to a developer between the exposed part and the unexposed part can be increased. Conceivably, PEB results in acceleration of dissociation of an acid-releasable group by the mediation of an acid generated by an acid-generating agent in the radiation-exposed portion of the resist film. The temperature at PEB is preferably 50 to 180° C., more preferably 80 to 130° C. The time of PEB is preferably 5 to 600 seconds, more preferably 10 to 300 seconds.

### [Development Step]

In this step, the resist film which has been exposed to the radiation in the above step is developed, whereby a resist pattern of interest can be formed. Generally, after development, the developed film is washed with a rinse liquid (e.g., water or alcohol) and then dried. The development method employed in the development step may be development with alkali or with organic solvent.

Examples of the developer employed in the alkali development include aqueous alkaline solutions in which at least one species from among alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo [5.4.0]-7-undecene, 1,5-diazabicyclo[4.3.0]-5-nonene, and the like is dissolved. Among such alkaline solutions, an aqueous TMAH solution is preferred. In the case of development with an organic solvent, examples of the developer include of one or more organic solvents (e.g., hydrocarbons, ethers, esters, ketones, and alcohols). Specific examples of the organic solvent used as a developer include the same solvents as exemplified in relation to, for example, the solvent (D) of the present composition. No particular limitation is imposed on the development method, and a known method may be appropriately selected.

### EXAMPLES

The present disclosure will next be described in detail by way of examples, which should not be construed as limiting the disclosure thereto. Physical properties were determined through the following procedures.

### [Weight Average Molecular Weight (Mw) and Number Average Molecular Weight (Mn)]

The weight average molecular weight (Mw) and the number average molecular weight (Mn) of a polymer were determined through gel permeation chromatography (GPC) with GPC columns (G2000HXL ×2, G3000HXL ×1, and G4000HXL ×1) (products of Tosoh Corp.) under the following conditions.
Eluent: tetrahydrofuran (product of FUJIFILM Wako Pure Chemical Corporation)
Flow rate: 1.0 mL/min
Sample concentration: 1.0 mass %
Sample injection: 100 UL
Column temperature: 40° C.
Detector: differential refractometer
Standard: monodispersed polystyrene

The structures of the radiation-sensitive acid-generating agents (PAG1 to PAG6, and PAGc1 to PAGc6), the acid diffusion control agents (Q-1 to Q-4, and Qc-1 to Qc-5), and the high-fluorine content resin (F-1) which were used for preparing radiation-sensitive resin compositions are as follows.

### [Radiation-Sensitive Acid-Generating Agent (PAG)]

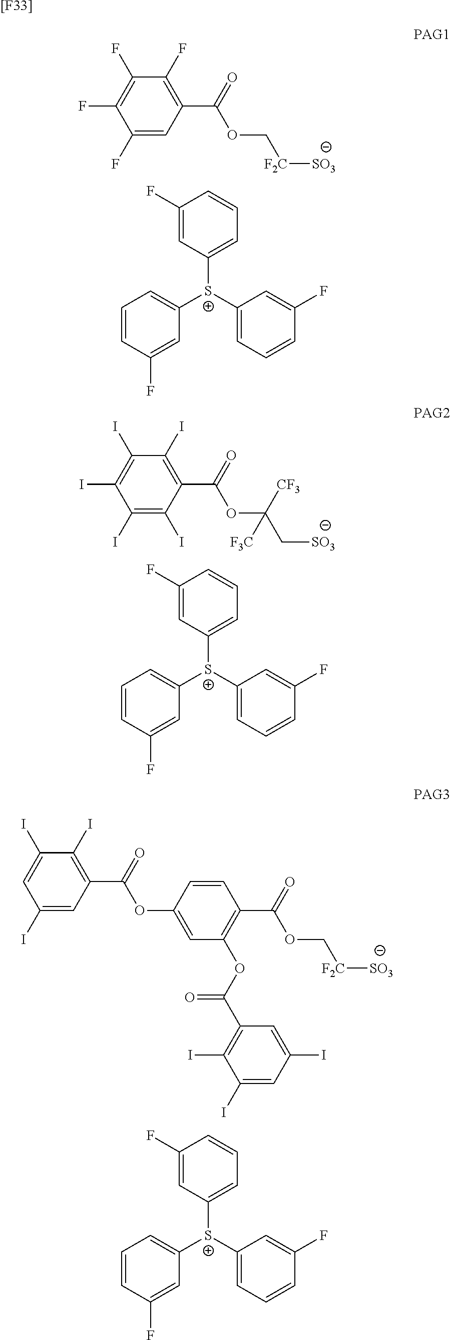

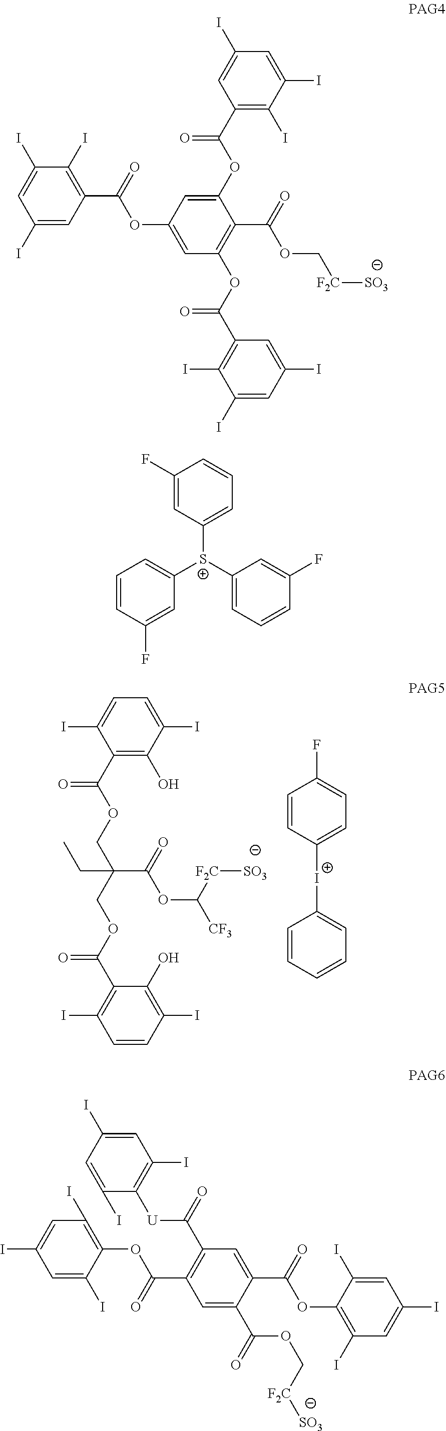

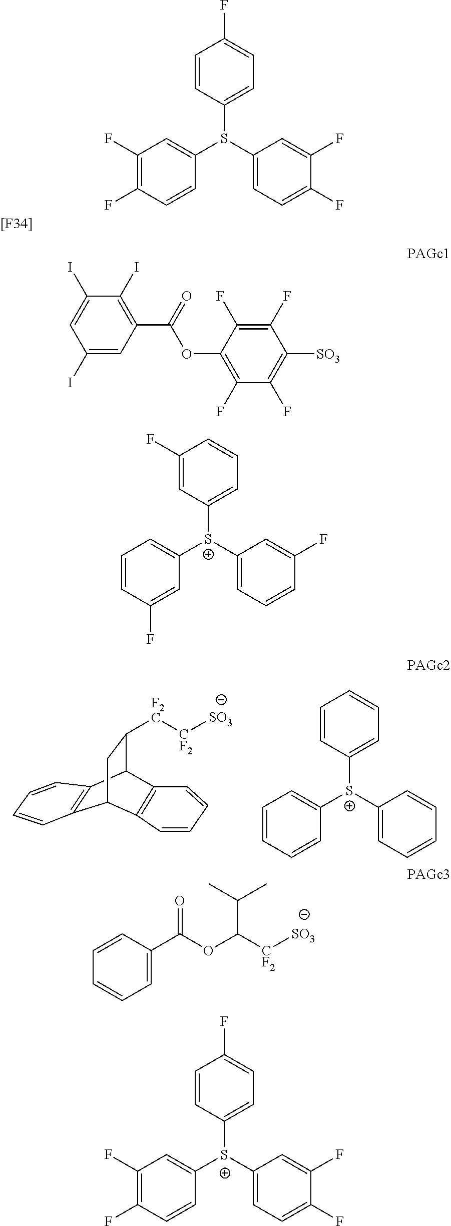

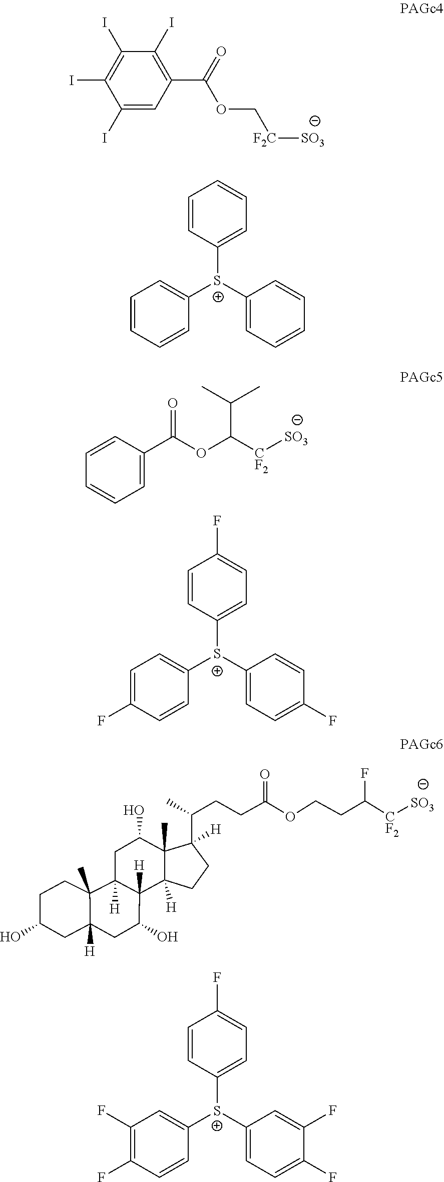

### [Acid Diffusion Control Agent]

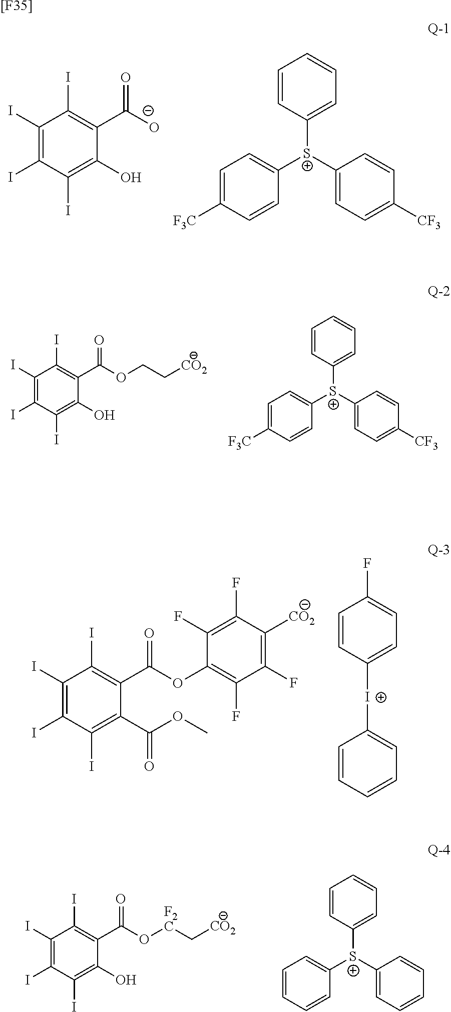

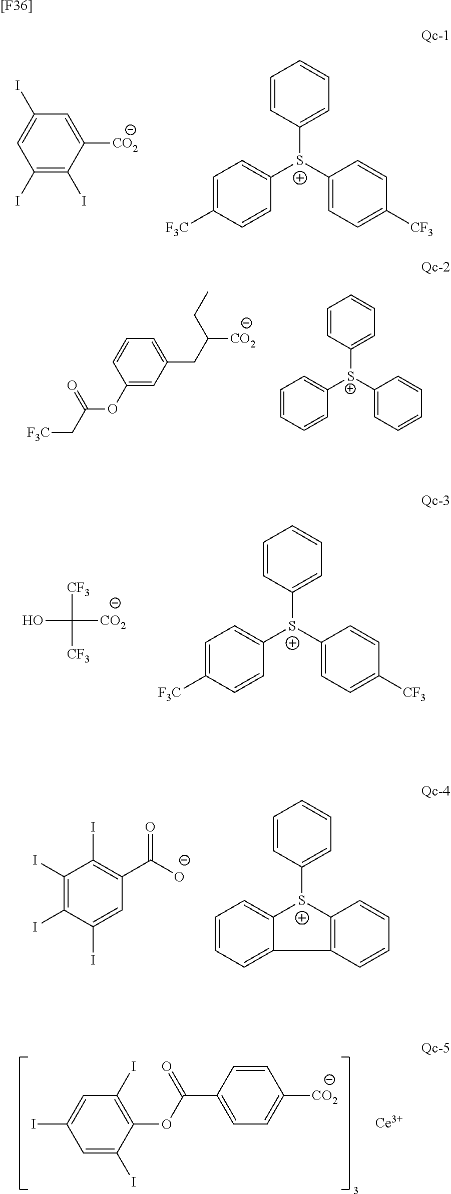

### [High-Fluorine Content Resin]

F-1: Mw=8,900, Mw/Mn=2.0

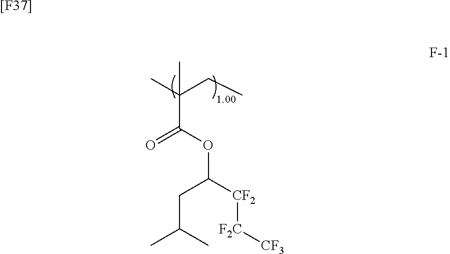

### Synthesis of Base Resins (P-1 to P-5)

Monomers of interest were chosen and co-polymerized in tetrahydrofuran (THF) as a solvent. The product was precipitated in methanol, repeatedly washed with hexane, isolated, and dried, to thereby yield polymers having the following compositions (mole ratios) (hereinafter may be referred to as “base resins,” polymers (P-1) to (P-5)). The composition of each of the yielded base resins was determined through 1H-NMR, and also Mw and dispersity (Mw/Mn) were determined through GPC (solvent: THF, standard: polystyrene). ¹H-NMR analysis was performed by means of a nuclear magnetic resonance apparatus (“JNM-ECZS400,” product of JEOL).
P-1: Mw=9,800, Mw/Mn=1.7
P-2: Mw=7,200, Mw/Mn=1.8
P-3: Mw=8, 100, Mw/Mn=1.7
P-4: Mw=9,400, Mw/Mn=1.7
P-5: Mw=9,700, Mw/Mn=1.6

### (Composition of Base Resin)

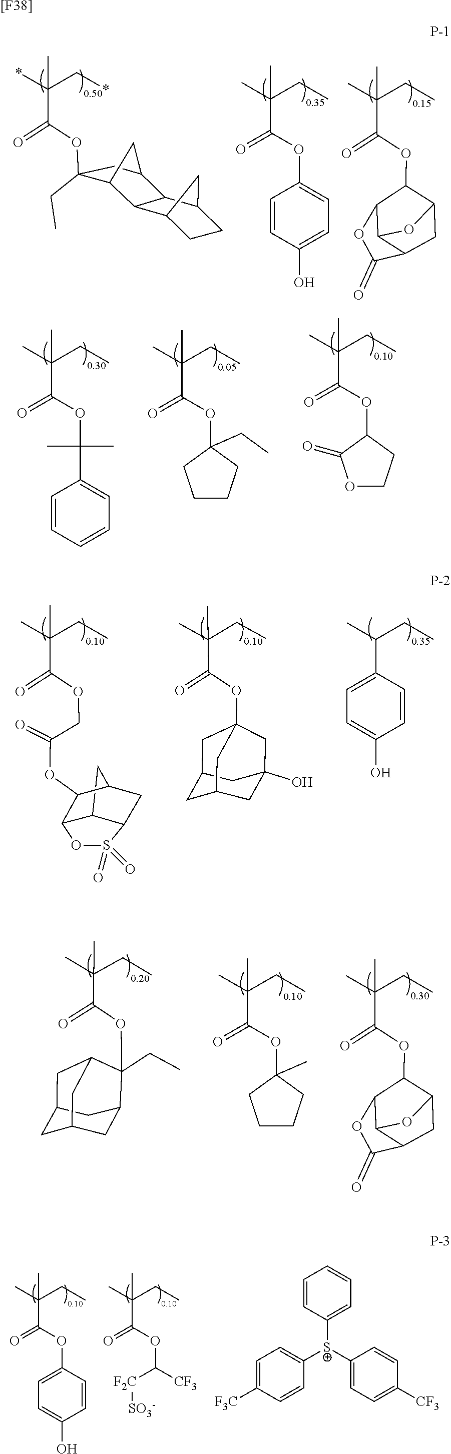

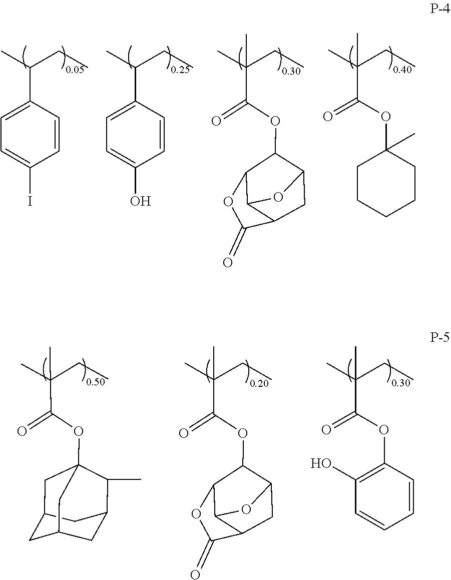

### Examples 1 to 10 and Comparative Examples 1 to 4

### 1. Preparation of Radiation-Sensitive Resin Compositions

In each case, components of interest shown Table 1 were dissolved in a solvent in which a surfactant (FC-4430, product of 3M) was dissolved at 100 ppm. The thus-prepared solution was filtered through a membrane filter (pore size: 0.2 μm), to thereby prepare a radiation-sensitive resin composition.

### 2. Evaluation of Sensitivity in Exposure to EUV

An underlayer-forming composition (“ARC66,” product of Brewer Science, Inc.) was applied onto a 12-inch silicon wafer by means of a spin coater (“CLEAN TRACK ACT12,” product of Tokyo Electron Limited), and heated at 205° C. for 60 seconds, to thereby form an underlayer film having an average thickness of 105 nm. Onto the thus-formed underlayer film, each of the radiation-sensitive resin compositions shown in Table 1 was applied by means of the aforementioned spin coater, and heated at 130° C. for 60 seconds for PB. Subsequently, the PB product was cooled at 23° C. for 30 seconds, to thereby form a resist film having an average thickness of 55 nm. The resist film was exposed to EUV by means of an EUV scanner (“NXE3300,” product of ASML (NA 0.33; σ 0.9/0.6, quadruple lighting, on-wafer dimension (pitch) 46 nm, and mask of a hole pattern with±20% bias)). After EUV exposure, the resist film was subjected to PEB on a hot plate at 120° C. for 60 seconds, and developed with 2.38-mass % aqueous tetramethylammonium hydroxide (TMAH) for 30 seconds, to thereby form a resist pattern (hole 23 nm, pitch 46 nm). The amount of exposure (dose) to form the resist pattern (hole 23 nm, pitch 46 nm) was employed as an optimum dose (Eop) serving as sensitivity (mJ/cm²). The smaller the value, the better the sensitivity. Table 1 shows the results.

### 3. Evaluation of CDU Performance

The procedure of “2.” above was repeated, to conduct exposure to EUV at an Eop as determined above, whereby another resist pattern (hole 23 nm, pitch 46 nm) was formed. The thus-formed resist pattern was observed under a scanning electron microscope (“CG-5000,” product of Hitachi High-Tech Corporation). The hole diameter was measured at 16 points within an area (diameter: 500 nm), and the measurements were averaged. The procedure was repeated so as to gain average measurements at 500 points at random. The 30 value was determined from the distribution of the measurements, and the determined 30 value was employed as an index for CDU performance (nm). The smaller the CDU performance index, the smaller the variation in hole diameter in a long period (i.e., the more favorable). Table 1 shows the results.

TABLE 1

| | base resin | PAG | acid diffusion | | additive | | |
|---|---|---|---|---|---|---|---|
| | (parts | (parts | control agent | solvent | (parts | sensitivity | CDU |
| | by mass) | by mass) | (parts by mass) | (parts by mass) | by mass) | [mJ/cm²] | [nm] |
| Example 1 | P-1 | PAG1 | Qc-1 | PGMEA/DAA | F-1 | 13 | 2.1 |
| | (100) | (7.5) | (3.0) | (2,000/500) | (3.0) | | |
| Example 2 | P-1 | PAG2 | Qc-1 | PGMEA/DAA | F-1 | 13 | 2.1 |
| | (100) | (7.5) | (3.0) | (2,000/500) | (3.0) | | |
| Example 3 | P-1 | PAG3 | Qc-1 | PGMEA/DAA | F-1 | 13 | 2.0 |
| | (100) | (7.5) | (3.0) | (2,000/500) | (3.0) | | |
| Example 4 | P-1 | PAG4 | Qc-1 | PGMEA/DAA | F-1 | 13 | 2.0 |
| | (100) | (7.5) | (3.0) | (2,000/500) | (3.0) | | |
| Example 5 | P-1 | PAGc1 | Q-1 | PGMEA/DAA | F-1 | 13 | 2.1 |
| | (100) | (7.5) | (3.0) | (2,000/500) | (3.0) | | |
| Example 6 | P-1 | PAGc1 | Q-2 | PGMEA/DAA | F-1 | 13 | 2.1 |
| | (100) | (7.5) | (3.0) | (2,000/500) | (3.0) | | |
| Example 7 | P-2 | PAG5 | Qc-2 | PGMEA/GBL | F-1 | 13 | 2.1 |
| | (100) | (6.5) | (3.0) | (2,200/300) | (3.0) | | |
| Example 8 | P-3 | PAG6 | Qc-2 | PGMEA/CHN/PGME | F-1 | 12 | 2.0 |
| | (100) | (5.5) | (2.5) | (800/1,500/200) | (3.0) | | |
| Example 9 | P-4 | PAGc2 | Q-3 | PGMEA/EL | F-1 | 13 | 2.1 |
| | (100) | (8.0) | (4.0) | (2,000/500) | (3.0) | | |
| Example 10 | P-5 | PAGc3 | Q-4 | PGMEA/PGME | F-1 | 13 | 2.1 |
| | (100) | (7.5) | (3.5) | (2,000/500) | (3.0) | | |
| Comparative | P-1 | PAGc1 | Qc-1 | PGMEA/DAA | F-1 | 14 | 2.2 |
| Example 1 | (100) | (7.5) | (3.0) | (2,000/500) | (3.0) | | |
| Comparative | P-1 | PAGc4 | Qc-3 | PGMEA/PGME | F-1 | 14 | 2.2 |
| Example 2 | (100) | (7.0) | (4.0) | (2,000/500) | (3.0) | | |
| Comparative | P-1 | PAGc5 | Qc-4 | PGMEA/CHN/PGME | F-1 | 14 | 2.2 |
| Example 3 | (100) | (8.0) | (3.0) | (800/1,500/200) | (3.0) | | |
| Comparative | P-1 | PAGc6 | Qc-5 | PGMEA/EL | F-1 | 12 | 2.2 |
| Example 4 | (100) | (5.5) | (2.0) | (2,000/500) | (3.0) | | |

The abbreviations of solvents in Table 1 are as follows.
PGMEA (propylene glycol monomethyl ether acetate)
GBL (γ-butyrolactone)
CHN (cyclohexanone)
PGME (propylene glycol monomethyl ether)
DAA (diacetone alcohol)
EL (ethyl lactate)

The resist patterns formed through EUV exposure were evaluated. The radiation-sensitive resin compositions of Examples 1 to 10 exhibited excellent sensitivity and CDU performance. In particular, in the case of employing PAG6 having 5 fluoro groups in a molecule thereof (Example 8), higher sensitivity was achieved. In the case of employing PAG having 6 or more iodo groups in a molecule thereof (Examples 3, 4, and 8), CDU performance was further enhanced.

In contrast, in Comparative Examples 1 to 4 employing an acid-generator (PAG, acid diffusion control agent) not containing a cation having group Rf¹ and an anion having 4 or more iodine atoms in the same molecule, CDU performance was inferior to that of Examples 1 to 10. Also, in Comparative Examples 1 to 3, sensitivity was lower than that of Examples 1 to 10.

According to the aforementioned radiation-sensitive resin composition and resist pattern formation method, a resist pattern exhibiting suitable sensitivity to exposure light and CDU performance can be formed. Thus, the invention 5 can be suitably applied to processing of semiconductor devices and the like, which conceivably require further process shrinkage.

1. A radiation-sensitive composition comprising:
(A) a polymer, and
(B) a radiation-sensitive acid-generator comprising an onium cation and an organic anion having 4 or more iodine atoms, the onium cation comprising at least one group Rf¹ selected from the group consisting of a fluoroalkyl group and a fluoro group which is not a fluoro group in the fluoroalkyl group.

2. The radiation-sensitive composition according to claim 1, wherein the organic anion has a structure in which 4 or more iodine atoms are bound to a single aromatic ring, or a structure which includes 2 or more aromatic rings to which an iodine atom is bound and in which the number of the iodine atoms bound to the aromatic rings is 4 or greater.

3. The radiation-sensitive composition according to claim 1, wherein the radiation-sensitive acid-generator (B) is a compound which can generate a sulfonic acid, a carboxylic acid, or a sulfonamide in the composition upon exposure to a radiation.

4. The radiation-sensitive composition according to claim 1, wherein the onium cation comprises a sulfonium cation structure or an iodonium cation structure.

5. The radiation-sensitive composition according to claim 1, wherein the onium cation comprises an aromatic ring Ar¹ bound to a sulfonium cation or an iodonium cation, and a structure in which the group Rf¹ is bound to the aromatic ring Ar¹.

6. The radiation-sensitive composition according to claim 1, wherein
the organic anion comprises a structure in which 4 or more iodine atoms are bound to a single aromatic ring, or a structure which includes 2 or more aromatic rings to which an iodine atom is bound and in which the number of the iodine atoms bound to the aromatic rings is 4 or greater, and
the onium cation comprises an aromatic ring Ar¹ bound to a sulfonium cation or an iodonium cation, and a structure in which the group Rf¹ is bound to the aromatic ring Ar¹.

7. The radiation-sensitive composition according to claim 1, wherein the polymer (A) comprises a structural unit having an acid-releasable group.

8. The radiation-sensitive composition according to claim 1, wherein the polymer (A) comprises a structural unit having a hydroxy group bound to an aromatic ring.

9. The radiation-sensitive composition according to claim 1, which is suitable for forming a resist pattern through exposure to an extreme ultraviolet ray.

10. The radiation-sensitive composition according to claim 1, further comprising a compound which can generate an acid weaker than an acid generated by the radiation-sensitive acid-generator (B) in the composition through exposure to a radiation.

11. The radiation-sensitive composition according to claim 1, further comprising a compound which can generate an acid stronger than an acid generated by the radiation-sensitive acid-generator (B) in the composition through exposure to a radiation.

12. A resist pattern formation method, comprising:
forming a resist film on a substrate by applying the radiation-sensitive composition according to claim 1;
exposing the resist film to a radiation; and
developing the exposed resist film.

13. The resist pattern formation method according to claim 12, wherein the resist film is exposed to an extreme ultraviolet ray.
